(19) United States
(12) Patent Application Publication
(10) Pub. No.: US 2026/0238183 A1
(43) Pub. Date: Aug. 13, 2026

(54) ACOUSTIC WAVE DEVICE IN TRAPEZOIDAL MODE

(71) Applicant: Qorvo US, Inc., Greensboro, NC (US)

(72) Inventor: Shogo Inoue, Greensboro, NC (US)

(21) Appl. No.: 19/154,642

(22) PCT Filed: Mar. 6, 2024
(86) PCT No.: PCT/US2024/018694

§ 371 Date: Aug. 7, 2025

Related U.S. Application Data
(60) Provisional application No. 63/490,486, filed on Mar. 15, 2023.
(60) Provisional application No. 63/585,641, filed on Sep. 27, 2023.

(51) Int. Cl. H03H 9/145; H03H 9/02; H03H 9/64

(52) U.S. Cl. CPC H03H 9/1452; H03H 9/02818; H03H 9/6433; H03H 9/02551

(57) ABSTRACT

An acoustic wave device includes a piezoelectric layer and an interdigital electrode structure. The interdigital electrode structure includes a plurality of first electrode fingers and second electrode fingers extending in a width direction. The plurality of first electrode fingers and the plurality of second electrode fingers are interleaved with one another along a length direction, the length direction being different from the width direction. At least one of the plurality of first electrode fingers or the plurality of second electrode fingers includes an edge portion between two ends of a respective electrode finger, a wave velocity of an acoustic wave propagating in the edge portion along the length direction is different from that outside of the edge portion. The at least one of the plurality of first electrode fingers or the plurality of second electrode fingers is apodized with an apodization pattern.

### CROSS-REFERENCE TO RELATED APPLICATIONS

The present application claims the benefit of U.S. Provisional Application No. 63/490,486 filed Mar. 15, 2023 and U.S. Provisional Application No. 63/585,641 filed Sep. 27, 2023, which are incorporated herein by reference in their entireties.

### FIELD OF THE DISCLOSURE

The present disclosure relates to surface acoustic wave resonators, in particular, to an acoustic wave device in trapezoidal mode.

### BACKGROUND

Acoustic wave devices are widely used in modern electronics. At a high level, an acoustic wave device often includes a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependence on the alternating electrical signal. Acoustic wave devices leverage this frequency dependence to provide one or more functions.

Exemplary acoustic wave devices include surface acoustic wave (SAW) resonators and bulk acoustic wave (BAW) resonators, which are increasingly used to form filters used in the transmission and reception of radio frequency (RF) signals for communication. Due to the stringent demands placed on filters for modern RF communications systems, acoustic wave devices for these applications must provide high quality factor, wide bandwidth (i.e., high electromechanical coupling coefficient), and be small in size. Often, undesired oscillations or vibrations are transduced in the piezoelectric material of an acoustic wave device which degrade the performance thereof. These undesired oscillations or vibrations are often referred to as spurious modes or transverse modes.

### SUMMARY

Embodiments of the disclosure provide an acoustic wave device having a piezoelectric layer and an interdigital electrode structure over the piezoelectric layer. The interdigital electrode structure includes a plurality of first electrode fingers and a plurality of second electrode fingers extending in a width direction. The plurality of first electrode fingers and the plurality of second electrode fingers are interleaved with one another along a length direction, the length direction being different from the width direction. At least one of the plurality of first electrode fingers or the plurality of second electrode fingers includes an edge portion between two ends of a respective electrode finger, a wave velocity of an acoustic wave propagating in the edge portion along the length direction is different from that outside of the edge portion. The at least one of the plurality of first electrode fingers or the plurality of second electrode fingers is apodized with an apodization pattern.

In some embodiments, the edge portion of the at least one of the plurality of first electrode fingers or the plurality of second electrode fingers form an edge region that has one of a straight line, an intermittent line, a staggered intermittent line, a non-linear line, or a broken line.

In some embodiments, the edge region extends partially or entirely in the plurality of first electrode fingers and the plurality of second electrode fingers.

In some embodiments, the apodization pattern includes a first apodization edge and a second apodization edge. The plurality of first electrode fingers extend from a first busbar towards the first apodization edge. The plurality of second electrode fingers extend from a second busbar towards the second apodization edge. The edge region is positioned between the first apodization edge and the first busbar or between the second apodization edge and the second busbar.

In some embodiments, the acoustic wave device further includes a plurality of first dummy electrodes extending from the second bus bar and a plurality of second dummy electrodes extending form the first bus bar. The plurality of first dummy electrodes are each aligned with a respective first electrode finger in the width direction and separated from the respective first electrode finger by a first gap. The plurality of second dummy electrodes are each aligned with a respective second electrode finger in the width direction and separated from the respective second electrode finger by a second gap.

In some embodiments, the edge region is positioned: between the first apodization edge and the second apodization edge; between the first busbar and the first gaps or between the second bus bar and the second gaps; or between a first portion of the first apodization edge and a second portion of the first apodization edge, or between a first portion of the second apodization edge and a second portion of the second apodization edge.

In some embodiments, the at least one of the plurality of first electrode fingers or the plurality of second electrode fingers includes a second edge portion between the two ends of the same respective electrode finger. The wave velocity of the acoustic wave propagating in the second edge portion along the length direction is different from that outside of the edge portion and the second edge portion. The second edge portion is positioned symmetrically or asymmetrically to the edge portion in the width direction about a middle position of the interdigital structure in the width direction.

In some embodiments, a maximum distance between an end of an electrode finger and a closest edge of a respective edge portion is greater than zero.

In some embodiments, the first apodization edge or the second apodization edge includes a repeated pattern or non-repeated pattern comprising at least one of a cosine wave pattern, a sine wave pattern, an arccosine pattern, a modified arccosine pattern, a multi-arccosine pattern, a weighted dummy electrode pattern, a slanted apodization pattern, a random apodization, a saw-shape pattern, a triangular-shape pattern, an intermittent wave pattern, or any shape of pattern.

In some embodiments, the first apodization edge and the second apodization edge have a same shape or are symmetric to each other.

In some embodiments, a width of the edge portion in the length direction is less than 2λ, λ being a wavelength of the acoustic wave propagating in the interdigital electrode structure.

In some embodiments, in the length direction, the width of the edge portion is different from a width of the rest of the respective electrode finger.

In some embodiments, the edge portion comprises an electrode layer disposed over the piezoelectric layer and a cover layer disposed over the electrode layer. The cover layer includes at least one of silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material, or a insulating material.

In some embodiments, the edge region includes a first cover layer over the piezoelectric layer between adjacent electrode fingers and the edge portion comprises a second cover layer disposed over an electrode layer. The first cover layer may be aligned with the second cover layer in the width direction. The first and second cover layers include at least one of silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material, or an insulating material.

In some embodiments, the edge region includes a cover layer over the piezoelectric layer between adjacent electrode fingers and the edge portion comprises an electrode layer. The cover layer may be aligned with the edge portion in the width direction. The cover layer includes at least one of silicon oxide (SiO), silicon nitride (SiN), tantalum oxide (TaₓO_{y}), silicon (Si), aluminum oxide (AlₓO_{y}), a metallic material, a semiconductor material, or an insulating material.

In some embodiments, the edge region further comprises a second cover layer under a respective electrode finger. The second cover layer includes at least one of silicon oxide (SiO), silicon nitride (SiN), tantalum oxide (TaₓO_{y}), silicon (Si), aluminum oxide (AlₓO_{y}), a metallic material, a semiconductor material, or an insulating material.

In some embodiments, a first distance between one of a first electrode finger or a second electrode finger and the respective periodic apodization function is less than a first predetermined percentage of an amplitude of the periodic apodization function. A second distance between one of a first dummy electrode or a second dummy electrode and the respective periodic apodization function is less than a second predetermined percentage of the amplitude of the periodic apodization function.

In some embodiments, the first percentage and the second percentage are each equal to or less than about 30%.

In some embodiments, a minimum overlap between adjacent first electrode finger and second electrode finger is equal to or greater than zero.

In some embodiments, the minimum overlap between adjacent first electrode finger and second electrode finger is equal to or greater than an opening percentage of a maximum overlap between adjacent first electrode finger and second electrode finger.

In some embodiments, the opening percentage is about 5%.

In some embodiments, the first apodization edge and the second apodization edge have a same apodization amplitude or different apodization amplitudes.

In some embodiments, the apodization pattern comprises a first period and a second period in the length direction, the first and second periods being the same or different.

In some embodiments, a number of the one or more periods is at least 3.

In some embodiments, a minimum length of the plurality of first dummy electrodes and the plurality of second dummy electrodes is less than 2λ, or equal to 0λ. λ is a wavelength of the acoustic wave propagating in the interdigital electrode structure.

In some embodiments, one of the plurality of first dummy electrodes is swapped with another one of the plurality of first dummy electrodes, and a first electrode finger aligned with the one of the plurality of first dummy electrodes is swapped with another first electrode finger aligned with the other one of the plurality of first dummy electrodes; or one of the plurality of second dummy electrodes is swapped with another one of the plurality of second dummy electrodes, and a second electrode finger aligned with the one of the plurality of second dummy electrodes is swapped with another second electrode finger aligned with the other one of the plurality of second dummy electrodes.

In some embodiments, the acoustic wave device further includes a grating reflector adjacent to the interdigital electrode structure in the length direction. The edge region extends partially or entirely in the grating reflector.

In some embodiments, the acoustic wave device further includes a grating reflector adjacent to the interdigital electrode structure in the length direction. The edge region does not extend into the grating reflector.

In some embodiments, the acoustic wave device further includes a substrate bonded with the piezoelectric layer. The thickness of the piezoelectric layer is less than or equal to 5λ, λ being a wavelength of an acoustic wave transmitted in the interdigital electrode structure.

In some embodiments, the piezoelectric layer includes lithium tantalate (LiTaO) or lithium niobate (LiNbO). The substrate includes at least one of silicon, sapphire, quartz, silicon carbide, spinel, ceramics, an insulating material, or a semiconductor material.

In some embodiments, the acoustic wave device further includes an intermediate layer between the piezoelectric layer and the substrate. The intermediate layer includes silicon oxide (SiO), tantalum oxide (TaₓO_{y}), such as SiO₂ and/or Ta₂O₅, a semiconductor material, or an insulating material.

In some embodiments, a first dummy electrodes and an adjacent second electrode finger are joined by a metal film. In some embodiments, a second dummy electrode and an adjacent first electrode finger are joined by another metal film.

Embodiments of the present disclosure provide a coupled resonator filter. The coupled resonator filter includes a plurality of acoustic resonators arranged in a length direction. Each of the acoustic resonators includes a piezoelectric layer, and a plurality of interdigital electrode structures over the piezoelectric layer. The plurality of interdigital electrode structures are insulated from one another. Each of the plurality of interdigital electrode structures includes a plurality of first electrode fingers and a plurality of second electrode fingers extending in a width direction. The plurality of first electrode fingers and the plurality of second electrode fingers interleaved with one another along a length direction, the length direction being different from the width direction. At least one of the plurality of first electrode fingers or the plurality of second electrode fingers includes an edge portion between two ends of a respective electrode finger, a wave velocity of an acoustic wave propagating in the edge portion along the length direction is different from that outside of the edge portion. The at least one of the plurality of first electrode fingers or the plurality of second electrode fingers is apodized with an apodization pattern.

In some embodiments, the first apodization edge or the second apodization edge comprises a repeated pattern.

In some embodiments, the first apodization edge or the second apodization edge comprises at least one of a cosine wave pattern, a sine wave pattern, an arccosine pattern, a modified arccosine pattern, a multi-arccosine pattern, a weighted dummy electrode pattern, a slanted apodization pattern, a random apodization, a saw-shape pattern, a triangular-shape pattern, or an intermittent wave pattern.

In some embodiments, the first apodization edge or the second apodization edge comprises a non-repeated pattern.

In some embodiments, the first apodization edge or the second apodization edge comprises at least one of a cosine wave pattern, a sine wave pattern, an arccosine pattern, a modified arccosine pattern, a weighted dummy electrode pattern, a slanted apodization pattern, a random apodization, a saw-shape pattern, a triangular-shape pattern, or an intermittent wave pattern.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIG. 1A illustrates an exemplary acoustic wave device in trapezoidal mode with apodization, according to some aspects of the present disclosure.

FIGS. 1B-1D, 1F, and 1H illustrate various configurations of an exemplary acoustic wave device in trapezoidal mode with apodization, according to some aspects of the present disclosure.

FIGS. 1E, 1G, and 1I illustrate cross-sectional views of different configurations of an exemplary acoustic wave device in trapezoidal mode with apodization, according to some aspects of the present disclosure.

FIG. 1J illustrates another configuration of an exemplary acoustic wave device in trapezoidal mode with apodization, according to some aspects of the present disclosure.

FIGS. 2A-2J illustrate various exemplary acoustic wave devices in trapezoidal mode with apodization, according to some aspects of the present disclosure.

FIGS. 3A-3C illustrate various exemplary acoustic wave devices in trapezoidal mode with apodizations, according to some aspects of the present disclosure.

FIGS. 4A-4I illustrate various apodizations employed in the acoustic wave devices in trapezoidal mode with apodizations, according to some aspects of the present disclosure.

FIGS. 5A-5D illustrate different numbers of periods in various apodizations employed in the acoustic wave devices in trapezoidal mode with apodization, according to some aspects of the present disclosure.

FIGS. 6A and 6B illustrate performances of an exemplary acoustic wave device in trapezoidal mode with apodization, according to some aspects of the present disclosure.

FIG. 7 illustrates another configuration of an exemplary acoustic wave device in trapezoidal mode with apodization, according to some aspects of the present disclosure.

FIGS. 8A and 8B illustrate an exemplary bonded wafer structure employing a acoustic wave device of trapezoidal mode with apodization, according to some aspects of the present disclosure.

FIG. 9 illustrates another exemplary bonded wafer structure employing a acoustic wave device in trapezoidal mode with apodization, according to some aspects of the present disclosure.

FIG. 10 illustrate a coupled resonator filter employing a plurality of acoustic wave devices in trapezoidal mode with apodizations, according to some aspects of the present disclosure.

FIG. 11 illustrates a plot of arccosine curves used as apodization edges employed in an acoustic wave device in trapezoidal mode with apodization, according to some aspects of the present disclosure.

FIG. 12 illustrates mode profiles of a plurality acoustic wave devices, according to some aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

As used herein, the term “layer” refers to a piece of a material. The term “layer” may encompass a wide range of thicknesses ranging from a few nanometers to several centimeters. For example, a layer may refer to a thin film of several nanometers to a few microns, or a substrate/wafer of a few hundred microns. The specific meaning of the term “layer” should be interpreted broadly based on the context, e.g., the Specification and the Claims, and should not be limited by the embodiments of the present disclosure.

As used herein, the term “repeated pattern” may refer to a pattern with two consecutive periods being identical in period lengths, amplitudes, and phases. In some embodiments, the term “repeated pattern” may refer to a pattern with two consecutive periods being identical in period lengths and amplitudes. In some embodiments, the term “repeated pattern” may refer to a pattern with two consecutive periods being identical in shape/function, but having different amplitudes, different period lengths, and/or different phases. The term “non-repeated pattern” may refer to a pattern with two consecutive periods having different shape/function.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein. Additionally, like reference numerals denote like features throughout specification and drawings.

An existing SAW resonator may have unwanted transverse modes and spurious modes which can hinder a practical use of the SAW resonator as a sole resonator or as a component of a filter. Effort has been made to suppress the transverse modes in an SAW resonator. For example, the transverse modes can be suppressed in a SAW resonator in piston mode (U.S. Pat. No. 7,939,989 B2). A SAW resonator in piston mode can also have desirably high electromechanical coupling coefficient k². However, a SAW resonator in piston mode may have degraded quality factor Q than a SAW resonator with apodization often because of transverse leakage or scattering loss. Improvement on quality factor Q in a SAW resonator in piston mode is needed.

Embodiments of the present disclosure provide an acoustic wave device in trapezoidal mode with apodization. The disclosed acoustic wave devices may have desirably high quality factor Q, high electromechanical coupling coefficient k², and desirable suppression of transverse modes. The proposed acoustic wave device may include an interdigital electrode structure that is apodized with one or more apodization edges, each which being part of a curve that follows a regular pattern and/or a random pattern. The interdigital electrode structure also includes one or more edge regions. The acoustic wave propagating in the interdigital electrode structure may have a different velocity traveling in an edge region than other parts of the interdigital electrode structure (or other parts of the electrode fingers). The edge portion may change/modify the SAW amplitude profile of the transverse mode, and can be a slow region in which the acoustic wave travels at a lower velocity or a fast region in which the acoustic wave travels at a higher velocity. The edge region(s) may modify the mode profiles in the transverse direction and thus modify the transverse modes.

The edge region(s) can be formed in various ways, such as changing the widths of the electrode fingers in the edge region, disposing additional materials on and/or below and/or between electrode fingers in the edge region, etc. The edge regions may have various configurations as it extends in the length direction and/or the width direction of the interdigital electrode structure. For example, the edge regions may each have a linear shape, a non-linear shape, an intermittent shape, and/or a random shape. The edge regions may extend in the interdigital electrode structure or beyond to the reflectors.

The apodization edges may include one or more periods in the length direction, while the amplitude and/or the length of period may vary or stay constant in different periods. For example, an apodization edge may include a repeated pattern or non-repeated pattern including a wave apodization, an arccosine apodization, a cosine/sine apodization, a modified arccosine apodization, weighted dummy apodization, a slanted apodization, a saw-shape apodization, a triangle-shape apodization, a random apodization, an intermittent wave apodization, and/or any shape of apodization. In some embodiments, the number of periods of the apodization edge may be at least 3.

In some embodiments, an acoustic wave device in trapezoidal mode with apodization can be used in other structures such as a bonded wafer structure and/or a coupled resonator filter (CRF) to suppress transverse modes and/or improve performance. For example, an acoustic wave device in trapezoidal mode with apodization can be used in a bonded wafer structure when transverse modes are present (e.g., the thickness of the piezoelectric layer is less than 5λ to suppress transverse modes, λ being the wavelength of the acoustic wave propagating in the interdigital electrode structure). In another example, a plurality of acoustic wave devices each in trapezoidal mode with apodization can be arranged in a CRF to suppress transverse modes.

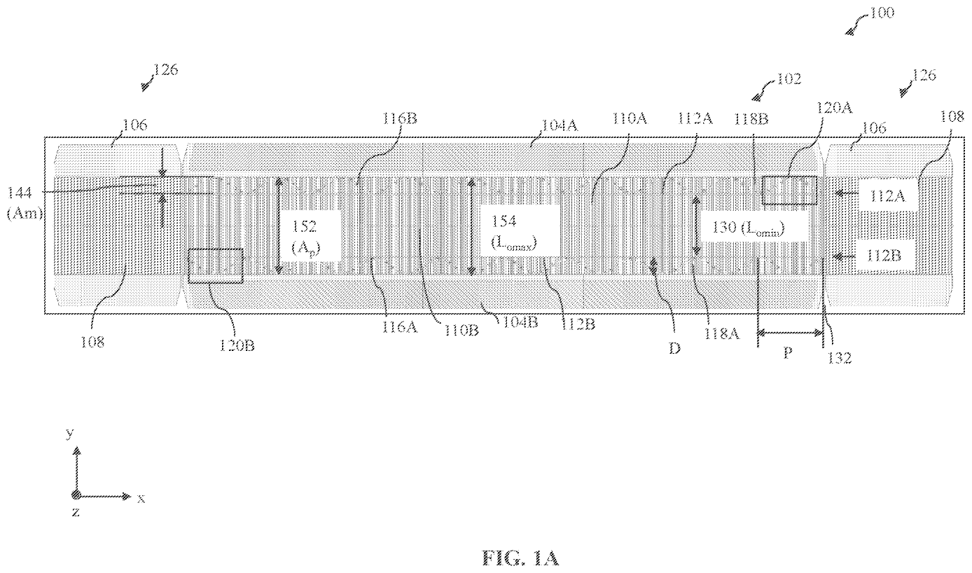

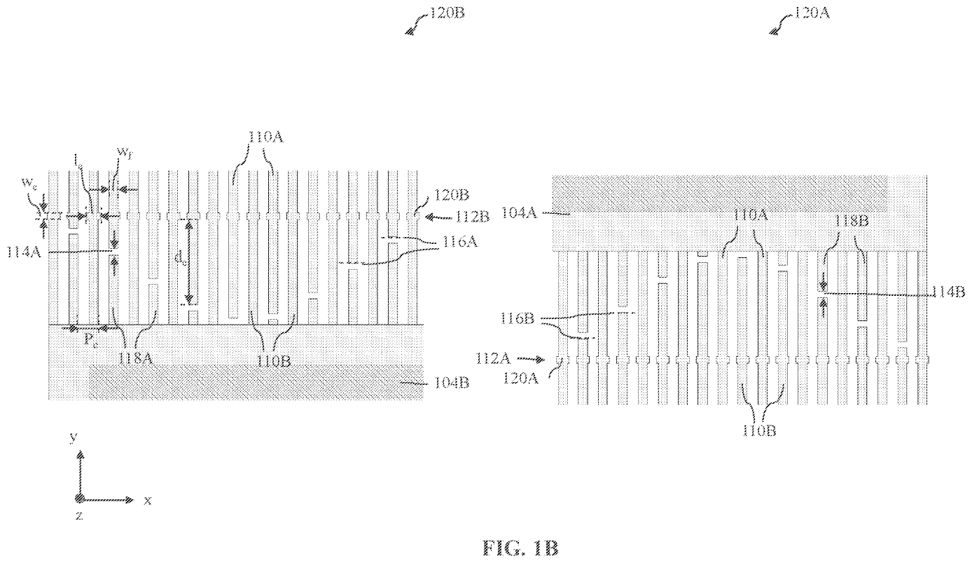

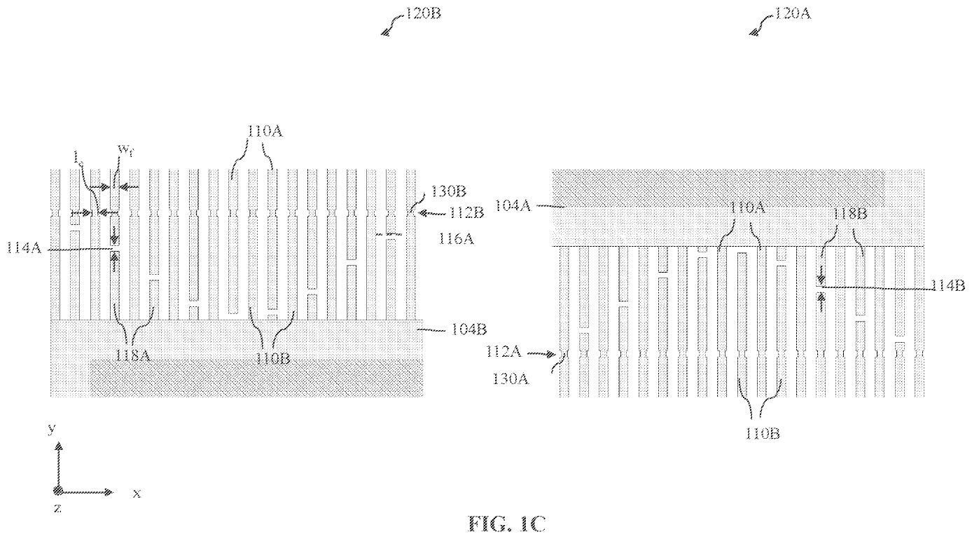

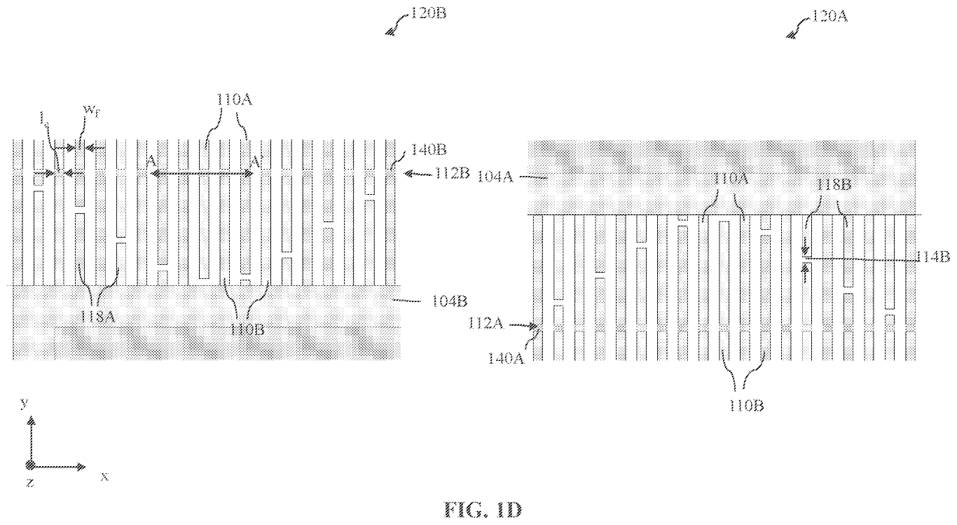

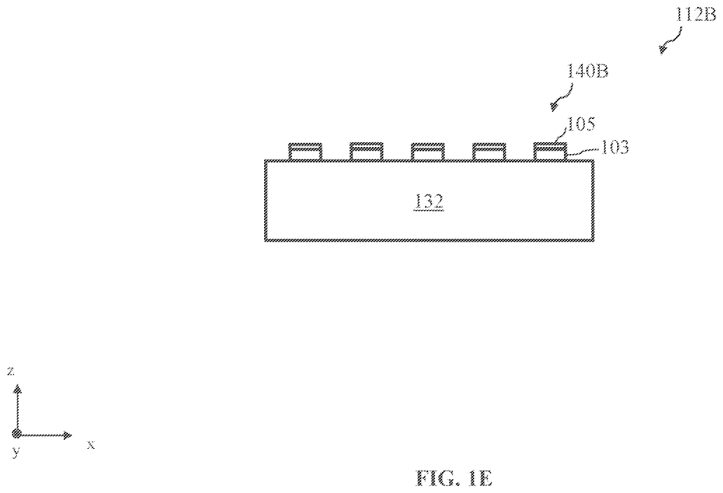

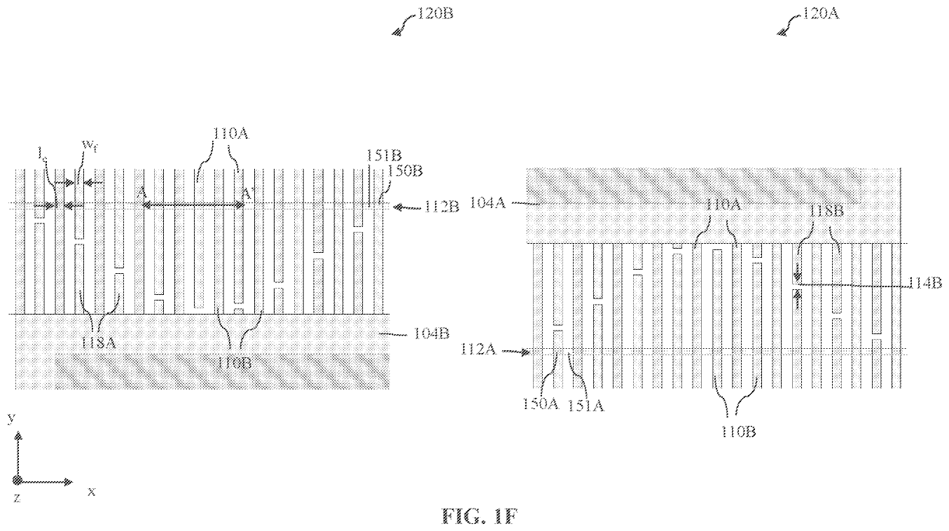

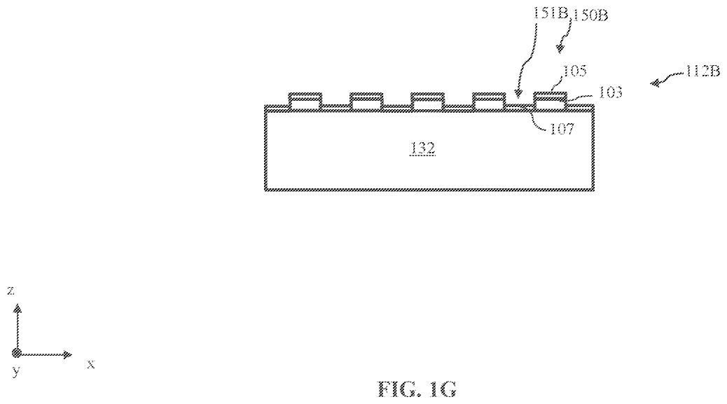

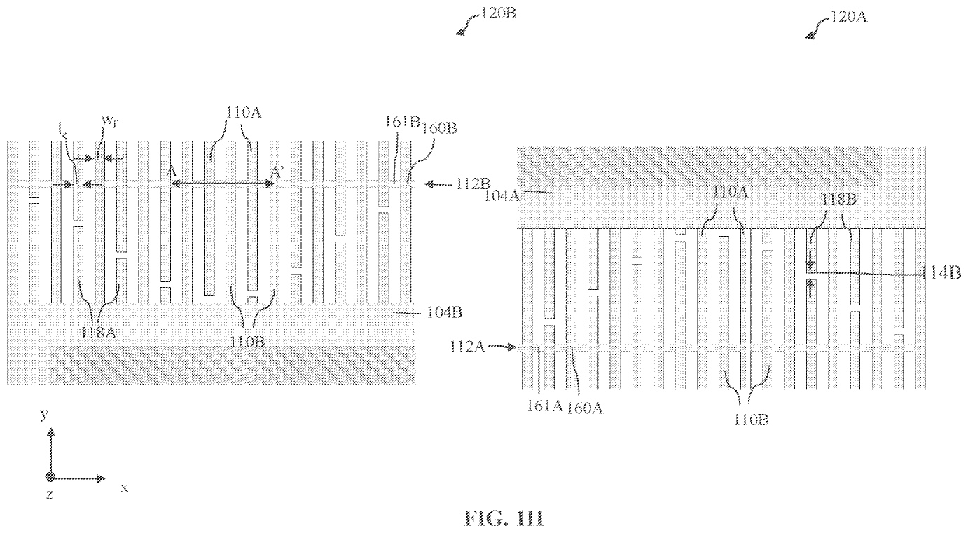

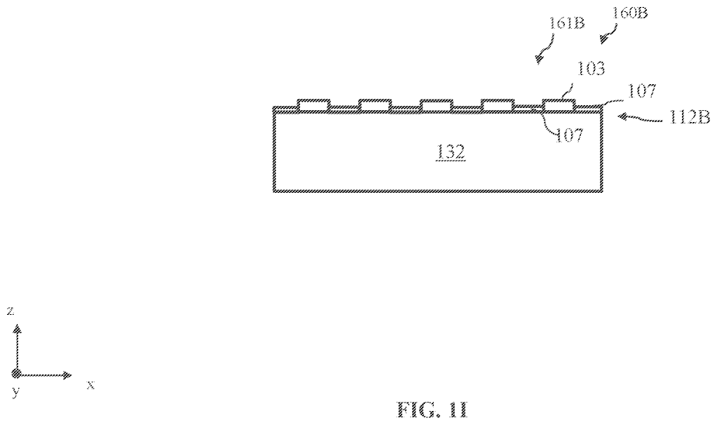

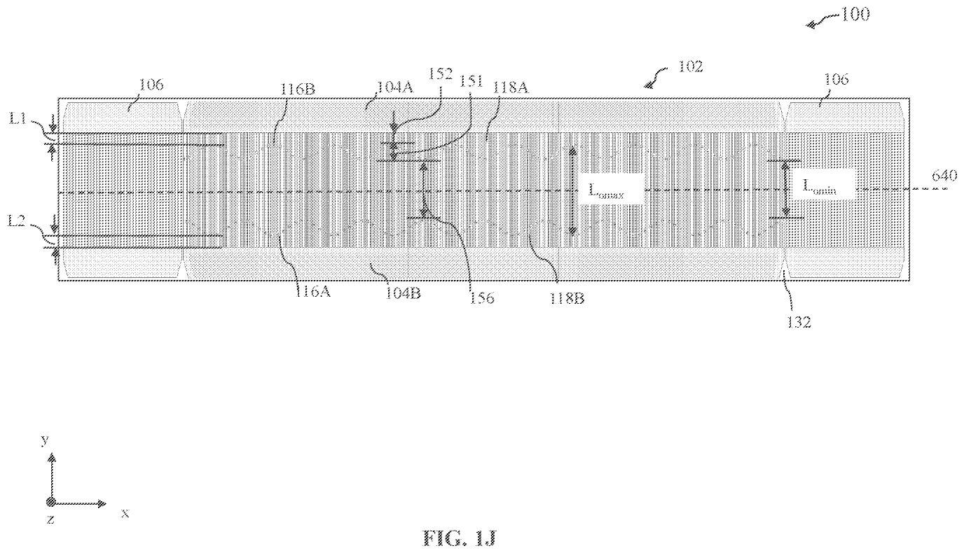

FIG. 1A illustrates an exemplary acoustic wave device 100 (e.g., a SAW resonator), according to embodiments of the present disclosure. Acoustic wave device 100 may include a piezoelectric layer 132, a pair of reflectors 126 over piezoelectric layer 132, and an interdigital electrode structure 102 positioned between reflectors 126. As shown in FIG. 1A, each reflector 126 may include a pair of reflector busbars 106 each extending in the x-direction (e.g., the length direction) and a plurality of reflector bars 108 extending between the pair of reflector busbars 106 in the y-direction (e.g., the width direction).

Interdigital electrode structure 102 may be aligned with reflectors 126 in the y-direction. Interdigital electrode structure 102 may include a first busbar 104A and a second busbar 104B each extending in the x-direction. Interdigital electrode structure 102 may include a plurality of first electrode fingers 110A extending from first busbar 104A in the y-direction, and a plurality of second electrode fingers 110B extending from second busbar 104B in the y-direction. An acoustic wave, having a wavelength of λ, may propagate in the first and second electrode fingers 110A and 110B along the x-direction. The plurality of first electrode fingers 110A may each extend to a first apodization edge 116A, and the plurality of second electrode fingers 110B may each extend to a second apodization edge 116B. In some embodiments, the distance between the centers of adjacent first electrode fingers 110A (e.g., in the x-direction) may be λ, and the distance between the centers of adjacent second electrode fingers 110B (e.g., in the x-direction) may be λ.

A first electrode finger 110A may overlap with at least one adjacent second electrode finger 110B (e.g., or both adjacent second electrode fingers 110B) in the y-direction, and a second electrode finger 110B may overlap with at least one adjacent first electrode finger 110A (e.g., or both adjacent first electrode fingers 110A) in the y-direction. The minimum overlap 130 between a first electrode finger 110A and an adjacent electrode finger 110B may be referred to as an “opening,” and may have a dimension (e.g., in the y-direction) of Lₒₘᵢₙ. In some embodiments, a maximum overlap 154 between a first electrode finger 110A and a second electrode finger 110B is normalized to be 1, and Lₒₘᵢₙ is a ratio (e.g., normalized value) between the actual dimensions of the minimum overlap and the actual dimension of maximum overlap 154 between a first electrode finger 110A and a second electrode finger 110B. For example, Lₒₘᵢₙ is a fraction between 0 and 1. In some embodiments, Lₒₘᵢₙ may be equal to or greater than zero such that there is desirable overlap between a first electrode finger 110A and an adjacent second electrode finger 110B in acoustic wave device 100. In some embodiments, Lₒₘᵢₙ is greater than 5% of Lₒₘₐₓ. In some embodiments, Lₒₘᵢₙ is greater than 10% of Lₒₘₐₓ. In some other embodiments, Lₒₘᵢₙ is greater than 15% of Lₒₘₐₓ.

First apodization edge 116A and/or second apodization edge 116B, across adjacent overlapping electrode fingers, and are provided as part of a curve/pattern in the x-direction. First apodization edge 116A and second apodization edge 116B may be employed to confine the lengths of electrode fingers and dummy electrodes, and thus define the apodization parameters of interdigital electrode structure 102. For example, first apodization edge 116A and second apodization edge 116B may extend in periods with an amplitude to cause the lengths of the electrode fingers and dummy electrodes to vary accordingly and periodically. In various embodiments, first apodization edge 116A and/or 116B may each include a periodic pattern and/or random pattern. In some embodiments, first apodization edge 116A and/or second apodization edge 116B may include a period P, e.g., a full period, which may be part of a periodic curve or a random curve starting at a horizontal axis (parallel to the x-direction) and having both a peak about the horizontal axis and a trough below the horizontal axis. In period P, first apodization edge 116A and/or second apodization edge 116B may have an amplitude 144 that is the distance between the highest peak and the lowest valley, and can be denoted as Am. In some embodiments, Am is between about 0.5λ and about 8λ. For example, Am may be 0.5λ, 1λ, 1.5λ, 2λ, 2.4λ, 2.6λ, 3λ, 3.5λ, 4λ, 5λ, 7 λ, 7.5 λ, 8λ, etc. An aperture 152 may be the largest distance between first apodization edge 116A and second apodization edge 116B in the y-direction. In some embodiments, the dimension of aperture 152 may be Aₚ and may be between about 5λ and about 25λ. For example, Aₚ may be 5λ, 5.5λ, 7λ, 8λ, 10λ, 12λ, 15λ, 18λ, 20λ, 21.5λ, 23.5λ, 24λ, 25λ, etc.

The maximum overlap 154 between a first electrode finger 110A and a second electrode finger 110B may have a dimension (e.g., length in the y-direction) of Lₒₘₐₓ. In some embodiments, when first apodization edge 116A and second apodization edge 116B are symmetric about middle line 140, maximum overlap 154 may be located between the peaks of first apodization edge 116A and second apodization edge 116B (e.g., at half period ½P). In some embodiments, the amplitude Am of first apodization edge 116A (or second apodization edge 116B) may be calculated as Am=Lₒₘₐₓ/2× (1−Lₒₘᵢₙ).

Interdigital electrode structure 102 may also include a plurality of first dummy electrodes 118A extending from second busbar 104B in the y-direction, and a plurality of second dummy electrodes 118B extending from first busbar 104A in the y-direction. A first dummy electrode 118A may be positioned between two adjacent second electrode fingers 110B, and a second dummy electrode 118B may be positioned between two adjacent first electrode fingers 110A. A first dummy electrode 118A may be aligned with a respective first electrode finger 110A in the y-direction, and a second dummy electrode 118B may be aligned with a respective second electrode finger 110B in the y-direction. A dummy electrode (e.g., dummy electrode 118A or 118B) may not have any overlap with an electrode finger from the different busbar. A gap (e.g., 114A and 114B illustrated in FIGS. 1B-1D, 1F, and 1H) between a dummy electrode and the respective electrode finger may have a dimension that is greater than zero.

In some embodiments, a minimum length L1 of a first dummy electrode 118A, in the y-direction, can be zero or non-zero, and a minimum length L2 of a second dummy electrode 118B, in the y-direction, can be zero or non-zero. In some embodiments, L1 and L2 may each be less than 2λ, less than λ, less than 0.5λ, less than 0.25λ, or 0. As an example, FIG. 1J illustrates L1 and L2 of non-zero values, while FIG. 1A illustrates L1 and L2 being approximate zero. In some embodiments, a smaller L1 and/or L2 may result in higher Q factor, higher electromechanical coupling coefficient k², and improved transverse mode suppression. In some embodiments, the area formed by the dummy electrodes extending from the same busbar may be referred to as an inactive area, and the area in which the electrode fingers overlap with one another may be referred to as an active area.

FIG. 1J also shows a center region 156, an apodized region 151, and a peripheral region 152. Center region 156 may be the area of interdigital electrode structure 102 between the closest points of first apodization edge 116A and second apodization edge 116B. In some embodiments, a dimension of center region 156 in the y-direction represents the smallest distance between the two apodization edges. Apodized region 151 may be the area in which an apodization edge extends. In some embodiments, a dimension of apodized region 151 in the y-direction represents the amplitude of an apodization edge. Peripheral region 152 may be the region between a peak of an apodization edge and the edge of the closest busbar. In some embodiments, peripheral region 152 is between the busbar and apodized area 151, and a dimension of peripheral region 152 in the y-direction may be the smallest distance between an apodization edge and the busbar.

Interdigital electrode structure 102 may include one or more edge regions 112A and/or 112B extending in the x-direction. Edge region 112A/112B may include portions of first electrode fingers 110A and/or second electrode fingers 110B extending in interdigital electrode structure 102. The acoustic wave may propagate at a different velocity in an edge region than other parts of the electrode fingers (or other parts of interdigital electrode structure 102). For example, the acoustic wave may propagate slower or faster in an edge region (e.g., edge region 112A or 112B) compared to other parts of the electrode fingers. In some embodiments, edge region 112A may be closer to first busbar 104A than second busbar 104B, and edge region 112B may be closer to second busbar 104B than first busbar 104A. For example, A distance D from the edge of a busbar to the center of the closest edge region may be between about 0 and about ½Aₚ. For example, D (between second busbar 104B and first edge region, and/or between first busbar 104A and second edge region) may be 0, 0.5λ, 0.6λ, 1λ, 1.2λ, 1.5λ, 2λ, 2.5λ, 2.72λ, 2.9λ, 3λ, 3.1λ, 3.5λ, 4λ, 4.2λ, 4.26λ, 5λ, 5.4λ, 6λ, 6.6λ, 7.5λ, etc. In some embodiments, as shown in FIG. 1A, edge regions 112A and 112B are symmetric about middle line 140. In some embodiments, a width (e.g., in the y-direction) of each of edge region 112A and edge region 112B may be greater than 0 and less than about 2λ. For example, the width may be less than 2λ, 1.5λ, 1.0λ, 0.75λ, 0.5λ, 0.25λ, 0.2λ, etc. In some embodiments, edge regions 112A and 112B may each be located away from the outer region such that the distance between edge region 112A/112B and the closest outer region is greater than zero. In some embodiments, edge regions 112A and 112B may each be located near the apodization edge which is created by the longest dummy electrode such that the distance between edge region 112A/112B and the closest outer region is greater than zero and close to, a little less, or a little more than amplitude 144.

FIG. 1B illustrates enlarged views of edge regions 112A and 112B in FIG. 1A in an example, according to some embodiments. Edge region 112A may include a plurality of edge portions 120A aligned in the x-direction, and edge region 112B may include a plurality of edge portions 120B aligned in the x-direction. Edge portion 120A/120B may have the same material (e.g., electrode material) as other parts of the respective electrode finger, and may be wider (e.g., in the x-direction) than parts of the electrode finger in the x-direction. As described above, a first dimension w_{c} of an edge portion (e.g., 120A or 120B) in the y-direction may be greater than 0 and less than 2λ, 1.5λ, 1.0λ, 0.75λ, 0.5λ, 0.25λ, 0.2λ, etc. In this embodiment, a second dimension lₑ of an edge portion (e.g., 112A or 112B) in the x-direction may be greater than that at other parts of the electrode fingers. In some embodiments, first and second electrode fingers 110A and 110B may have a constant dimension w_{f} (e.g., in the x-direction) outside the respective edge portions. In some embodiments, a duty factor of an edge portion (e.g., 120A/120B) may be greater than that of the part of an electrode finger outside edge regions 112A and 112B. The duty factor of an edge portion may be calculated as lₑ/P_{c}, where Pc represents the pitch distance between the same sides of two adjacent electrode fingers in the x-direction, as shown in FIG. 1B. The duty factor of an electrode finger (e.g., part of the electrode finger outside the edge portion) may be calculated as w_{f}/P_{c}. The duty factor of an edge portion (e.g., 120A or 120B) lₑ/P_{c} may be between about 40% and about 80%, and the duty factor of an electrode finger outside edge regions w_{f}/P_{c} may be about 30% to about 70%. In some embodiments, lₑ/P_{c} is about 5 points to about 50 points greater than w_{f}/P_{c}. For example, if w_{f}/P_{c} is 50% and lₑ/P_{c} is 65%, the difference is about 15 points.

In some embodiments, a maximum distance dₑ between the end of one or more electrode fingers and the closest edge of the respective edge portion is greater than zero and can be similar to or greater than amplitude 144. In some embodiments, maximum distance dₑ between the end of the first electrode finger 110A and the closest edge of edge region 120B is greater than zero and can be similar to or greater than amplitude 144. Similarly, maximum distance dₑ between the end of the second electrode finger 110B and the closest edge of edge region 120A is greater than zero and can be similar to or greater than amplitude 144. In various embodiments, the minimum value of distance dₑ can be zero or less than 0.1λ, 0.2λ, 0.3λ, 0.5λ, 1.0λ, 1.5λ, 2.0λ, 2.5λ, 3.0λ, and maximum value of distance dₑ can be more than 0.5λ, 1λ, 1.5λ, 2λ, 3λ, 5λ, 10λ, 20λ. The pattern/locations of the edge regions may contribute to a better transverse mode suppression and a higher quality factor compared to the pattern/locations where the edge region is located on the end of the respective electrode finger (e.g., an acoustic device in piston mode).

FIG. 1C illustrates an enlarged views of edge regions 112A and 112B in FIG. 1A in another example, according to some embodiments. Edge region 112A may include a plurality of edge portions 130A aligned in the x-direction, and edge region 112B may include a plurality of edge portions 130B aligned in the x-direction. Edge portion 130A/130B may have the same material (e.g., electrode material) as other parts of the respective electrode finger, and may be narrower (e.g., in the x-direction) than other parts of the electrode finger. Different from the embodiment illustrated in FIG. 1B, in this embodiment, a second dimension lₑ of an edge portion (e.g., 130A or 130B) in the x-direction may be less than wf at other parts of the electrode fingers. L_{c}/P_{c} may be between about 10% and about 60%, and w_{f}/P_{c} may be about 30% to about 80%. In some embodiments, le/P_{c} may be about 5 points to about 50 points less than w_{f}/P_{c}.

FIG. 1D illustrates an enlarged views of edge regions 112A and 112B in FIG. 1A in another example, according to some embodiments. Edge region 112A may include a plurality of edge portions 140A aligned in the x-direction, and edge region 112B may include a plurality of edge portions 140B aligned in the x-direction. Edge portion 140A/140B may include the electrode material as other parts of the respective electrode finger, and a layer of a velocity-changing material. In this embodiment, a second dimension lₑ of an edge portion (e.g., 140A or 140B) in the x-direction may or may not be the same as dimension w_{f} (e.g., in the x-direction) of an electrode finger outside the respective edge portion. In some embodiments, a duty factor of an edge portion (e.g., 140A/140B) may or may not be the same as that of the part of an electrode finger outside the edge portion. In some embodiments, the edge of the edge portion in FIGS. 1B, 1C, and/or 1D are not necessarily right angle, it can be rounded or beveled.

FIG. 1E illustrates a cross-sectional view of part of edge region 112B (e.g., shown in FIG. 1D) in the AA′ direction (parallel to the x-direction). Edge region 112A may be similar to edge region 112B and the description is not repeated. While outside the edge region (e.g., edge regions 112B and 112A), first electrode fingers 110A and second electrode fingers 110B may include an electrode layer including material such as metal (e.g., tungsten, copper, aluminum, and/or cobalt), edge portion 140B may include an electrode layer 103 and a cover layer 105 disposed on top of electrode layer 103. In some embodiments, edge portion 140B may include a cover layer (not shown) disposed at the bottom of electrode layer 103 (e.g., between electrode layer 103 and piezoelectric layer 132). In some embodiments, cover layer 105 includes a velocity-change material that facilitates the acoustic wave to propagate at a velocity different from that of other parts of the electrode finger. In some embodiments, cover layer 105 includes the same material as for the electrode layer 103 or a material different from electrode layer 103, such as silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material and/or an insulating material. In some embodiments, the part of piezoelectric layer 132 between two adjacent edge portions 140B (or two adjacent electrode fingers) is exposed, e.g., not covered with a cover layer.

FIG. 1F illustrates an enlarged views of edge regions 112A and 112B in FIG. 1A in another example, according to some embodiments. Edge region 112A may include a plurality of first edge portions 150A aligned in the x-direction, and edge region 112B may include a plurality of first edge portions 150B aligned in the x-direction. First edge portions 150A and second edge portions 150B may include parts in the electrode fingers. Different from the structure in FIGS. 1D and 1E, edge regions 112A and 112B in this embodiment may also respectively include a plurality of second edge portions 151A and a plurality of second edge portions 151B. A second edge portion (e.g., 151A/151B) may be disposed between adjacent first edge portions (or electrode fingers) in the x-direction. In some embodiments, a second edge portion (e.g., 151A/151B) may include a cover layer disposed on piezoelectric layer 132. In this embodiment, a second dimension lₑ of a first edge portion (e.g., 150A or 150B) in the x-direction may or may not be the same as dimension w_{f} (e.g., in the x-direction) of an electrode finger outside the respective edge portion. In some embodiments, a duty factor of a first edge portion (e.g., 150A/150B) may or may not be the same as that of the part of an electrode finger outside the edge portion.

FIG. 1G illustrates a cross-sectional view of part of edge region 112B in the AA′ direction (parallel to the x-direction). Edge region 112A may be similar to edge region 112B and the description is not repeated. While outside the edge region (e.g., edge regions 112B and 112A), first electrode fingers 110A and second electrode fingers 110B may include an electrode layer including material such as metal (e.g., tungsten, copper, aluminum, and/or cobalt), first edge portion 150B may include an electrode layer 103 and a first cover layer 105 disposed on top of each electrode layer 103. In some embodiments, edge portion 150B may include a cover layer (not shown) disposed at the bottom of electrode layer 103 (e.g., between electrode layer 103 and piezoelectric layer 132). Second edge portion 151B may include a second cover layer 107 disposed on the part of piezoelectric layer 132 between adjacent first edge portions 150B (or adjacent electrode fingers). In some embodiments, first cover layer 105 and second cover layer 107 each includes a velocity-change material that facilitates the acoustic wave to propagate at a velocity different from that of other parts of the electrode finger, without changing the dimension of the electrode finger. In some embodiments, first cover layer 105 and second cover layer 107 each includes a non-metal material, such as silicon oxide (SiO), silicon nitride (SiN), tantalum oxide (TaₓO_{y}), silicon (Si), aluminum oxide (AlₓO_{y}), a metallic material, a semiconductor material, and/or insulating material. In some embodiments, second cover layer 107 extends continuously in the x-direction, and electrode layer 103 is disposed on second cover layer 107. In some embodiments, first cover layer 105 may or may not be formed. For example, electrode layer 103 may be sandwiched between first cover layer 105 and second cover layer 107, or may be disposed on second cover layer 107 without first cover layer 105 on top.

FIG. 1H illustrates an enlarged views of edge regions 112A and 112B in FIG. 1A, according to some embodiments. Edge region 112A may include a plurality of first edge portions 160A aligned in the x-direction, and edge region 112B may include a plurality of first edge portions 160B aligned in the x-direction. First edge portions 160A and second edge portions 160B may include parts in the electrode fingers (e.g., without a cover layer). Different from the structure in FIGS. 1D and 1E, edge regions 112A and 112B in this embodiment may also respectively include a plurality of second edge portions 161A and a plurality of second edge portions 161B. A second edge portion (e.g., 161A/161B) may be disposed between adjacent first edge portions (or electrode fingers) in the x-direction. In some embodiments, a second edge portion (e.g., 161A/161B) may include a cover layer disposed on piezoelectric layer 132. In this embodiment, a second dimension lₑ of a first edge portion (e.g., 160A or 160B) in the x-direction may or may not be the same as dimension w_{f} (e.g., in the x-direction) of an electrode finger outside the respective edge portion. In some embodiments, a duty factor of a first edge portion (e.g., 160A/160B) may or may not be the same as that of the part of an electrode finger outside the edge portion.

FIG. 1I illustrates a cross-sectional view of part of edge region 112B in the AA′ direction (parallel to the x-direction). Edge region 112A may be similar to edge region 112B and the description is not repeated. First edge portion 160B may include an electrode layer 103 that includes electrode material such as metal (e.g., tungsten, copper, aluminum, and/or cobalt), without any cover layer on top of electrode layer 103. Second edge portion 161B may include a cover layer 107 disposed on the part of piezoelectric layer 132 between adjacent first edge portions 160B (or adjacent electrode fingers). In some embodiments, cover layer 107 each includes a velocity-change material that facilitates the acoustic wave to propagate at a velocity different from that of other parts of the electrode finger, without changing the dimension of the electrode finger. In some embodiments, cover layer 107 each includes a non-metal material, such as silicon oxide (SiO), silicon nitride (SiN), tantalum oxide (TaₓO_{y}), silicon (Si), and/or aluminum oxide (AlₓO_{y}), a semiconductor material, an insulating material and/or a metallic material.

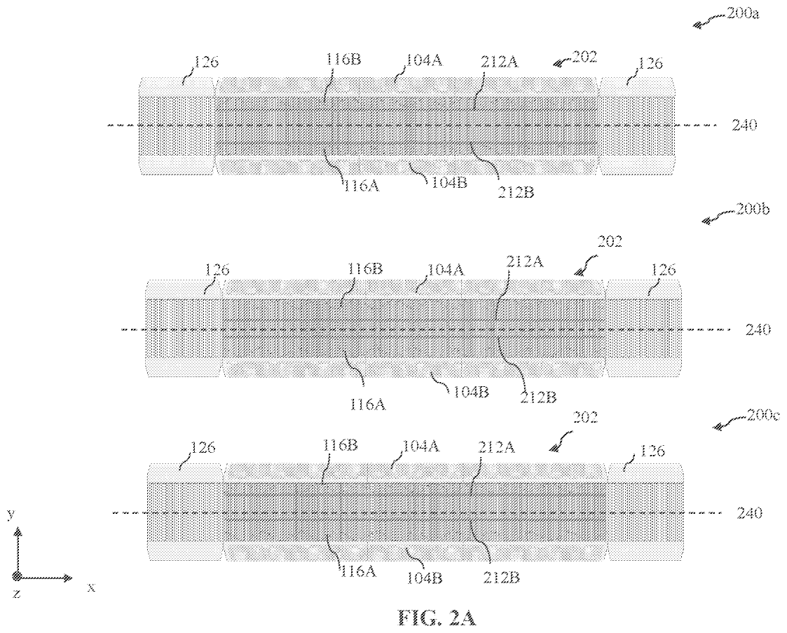

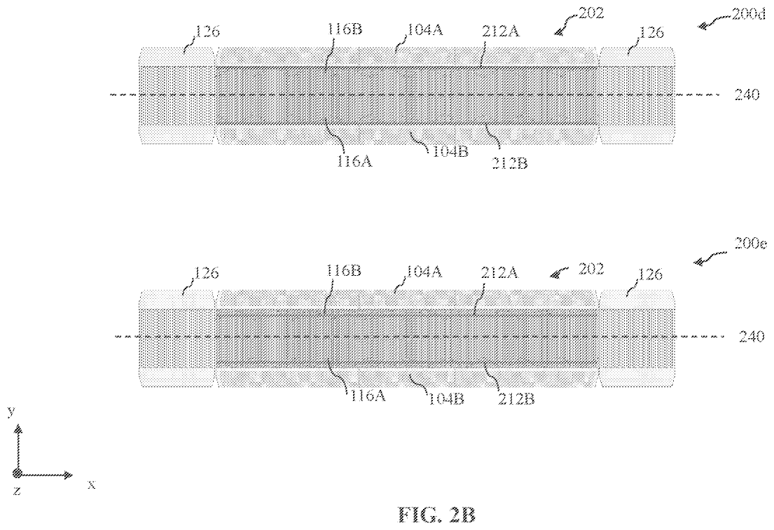

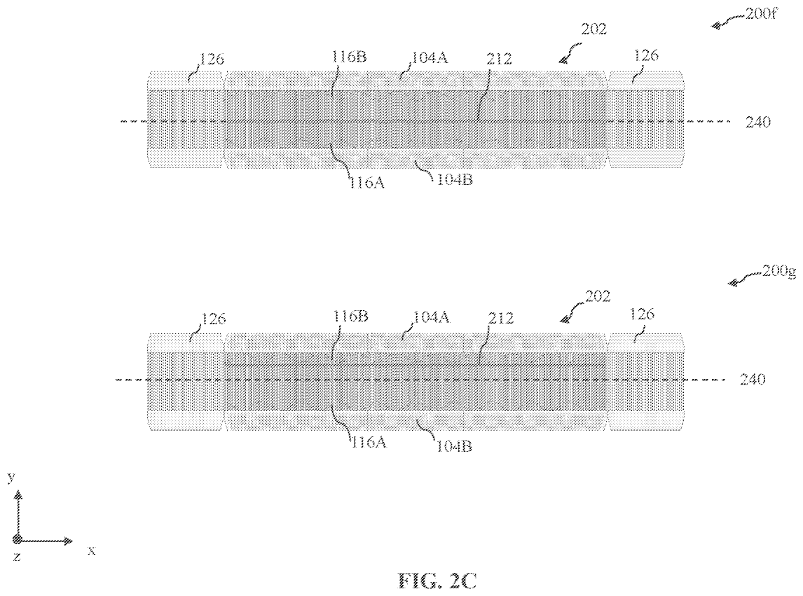

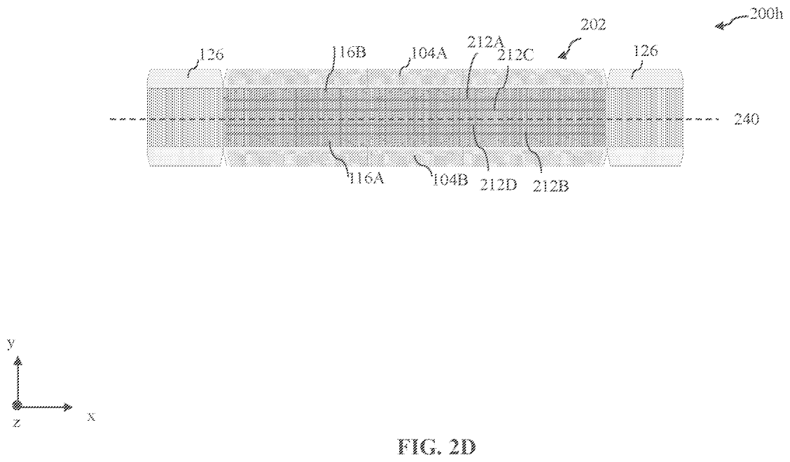

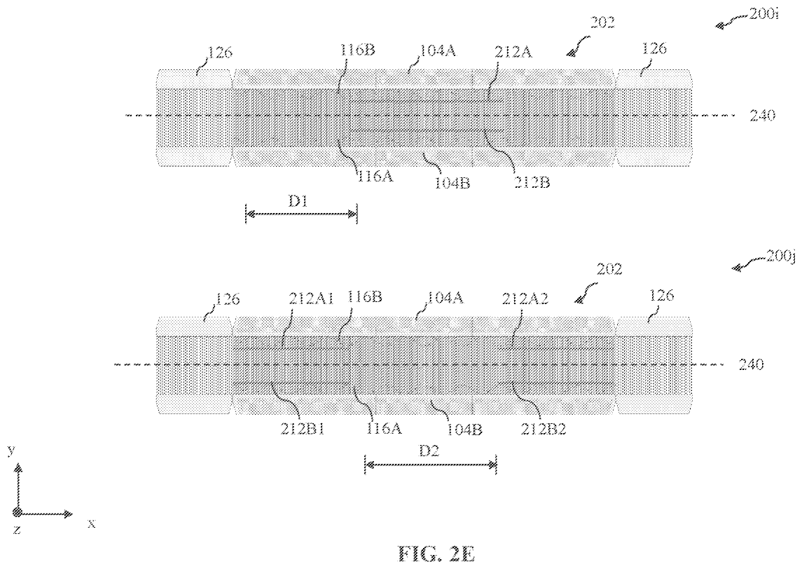

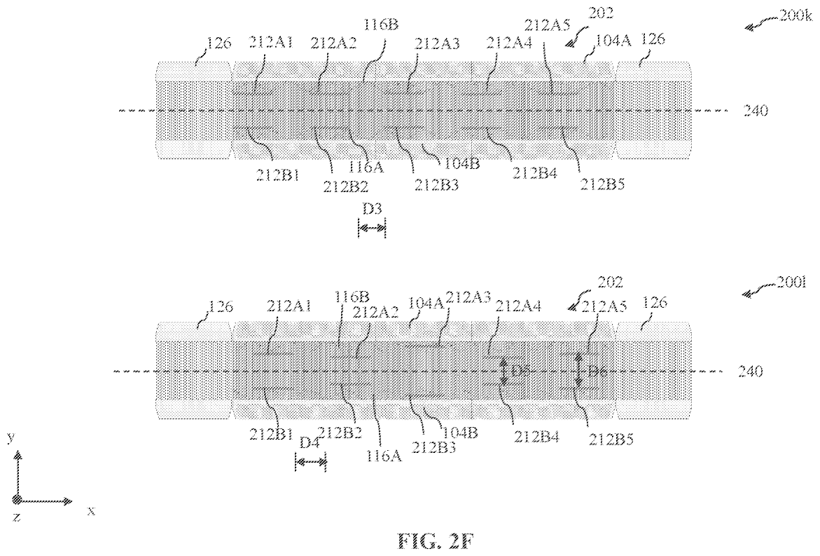

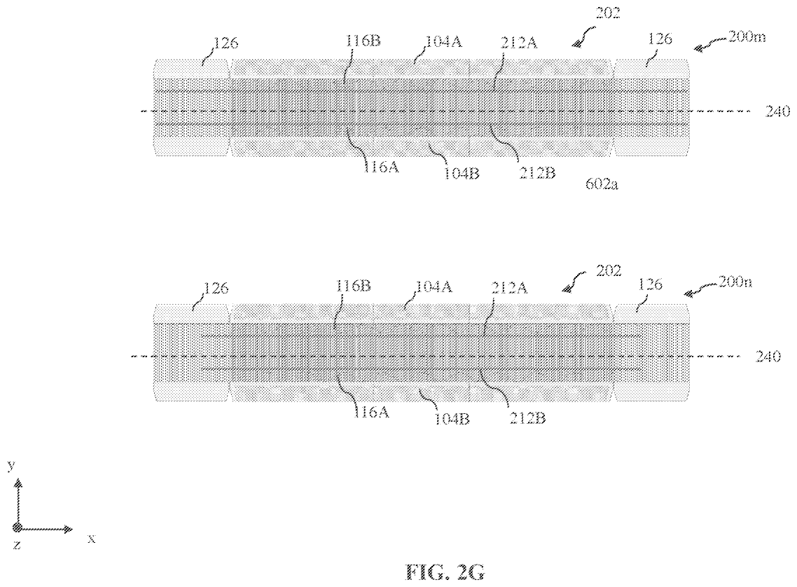

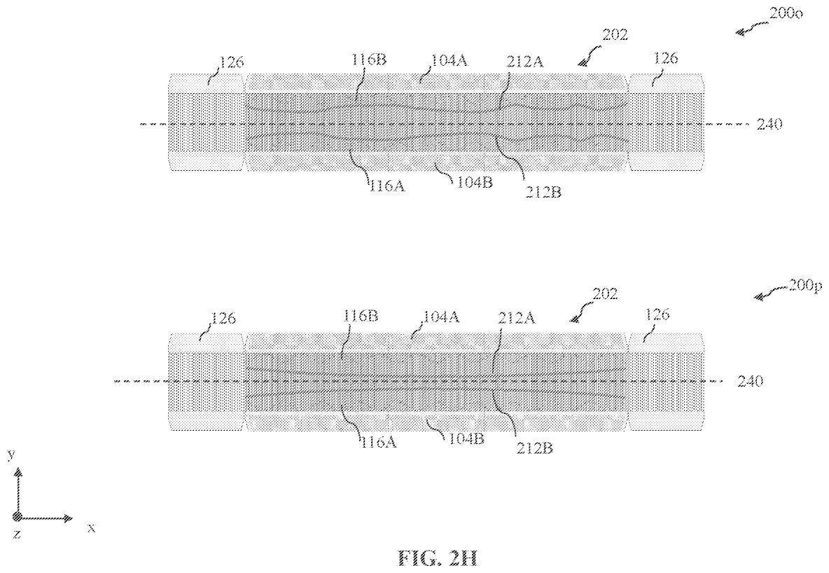

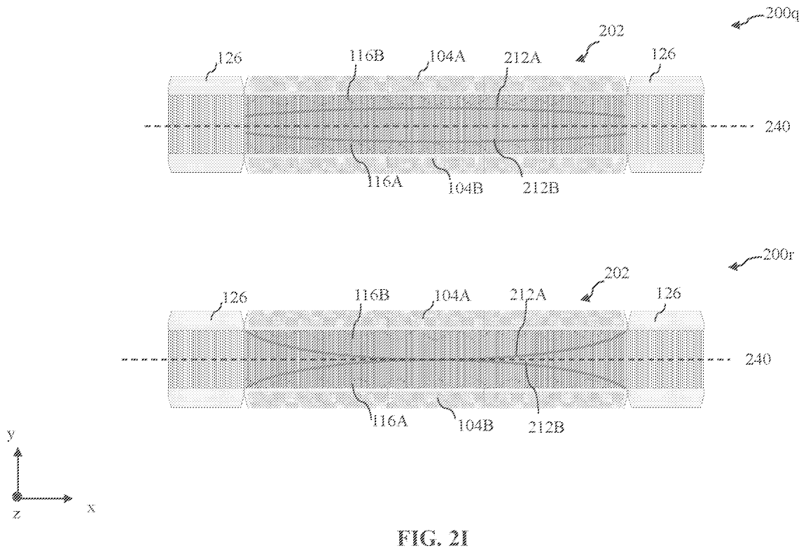

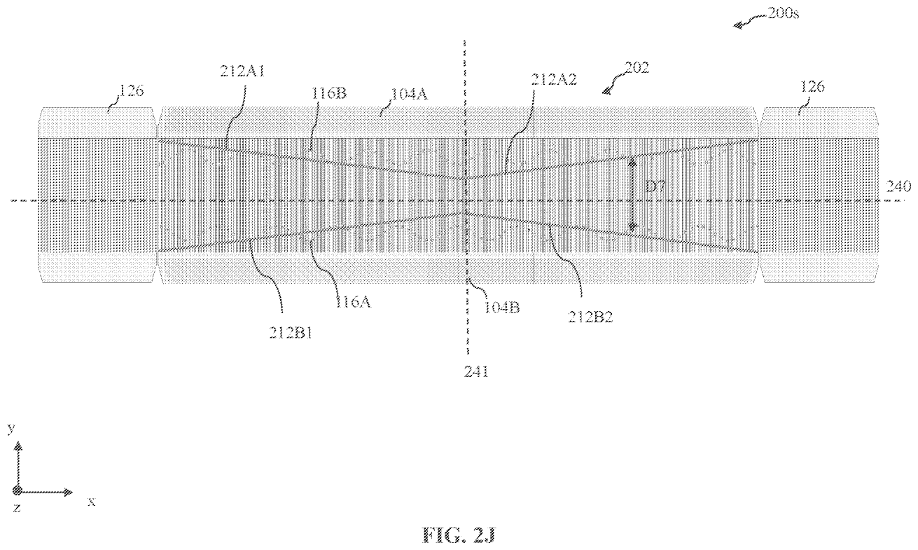

FIGS. 2A-2J illustrate various configurations of edge regions in a plurality of acoustic wave devices 200a-200s, according to some embodiments. Each of acoustic wave devices 200a-200s may include an interdigital electrode structure 202. For ease of illustration, the piezoelectric layer is not shown in the figures, and the apodization edges are shown to be the same (e.g., wave apodization edges symmetric about a middle line 240 of interdigital electrode structure 202) in acoustic wave devices 200a-200s. It should be noted that, in various embodiments, the patterns/curves of apodization edges may vary, and should not be limited by the embodiments of the present disclosure. In acoustic wave devices 200a-200s, the edge regions in the same acoustic wave device may be the same or different. The edge regions in acoustic wave devices 200a-200s may be used in any acoustic wave devices in trapezoidal mode in this disclosure. In acoustic wave devices 200a-200s, the apodization edges may each be a wave apodization edge with opening (e.g., Lₒₘᵢₙ being greater than zero), and may follow a wave function y=±{Lₒₘᵢₙ+(cos x+1)/2×(1−Lₒₘᵢₙ)}, −π≤x≤+π.

In various embodiments, first dimension we of an edge region may be constant or may vary. In some embodiments, first dimension We may be dependent on the pitch of the electrode finger and/or the widths of the electrode fingers. The center positions of the two adjacent edge portions with the different widths may or may not align in the x-direction. The ratio of the maximum value of we (wₑₘₐₓ) and the minimum value of we (wₑₘᵢₙ) of the edge region, i.e., wₑₘₐₓ/wₑₘᵢₙ can be from 1 to 1.05/1.1/1.2/1.3/1.5/2/3. Also, second dimension le of an edge region may be constant or may vary. In some embodiments, second dimension lₑ may be dependent on the pitch of the electrode finger and/or the widths of the electrode fingers. The ratio of the maximum value of lₑ (lₑₘₐₓ) and the minimum value of lₑ (lₑₘᵢₙ) of the edge regions, i.e., lₑₘₐₓ/lₑₘᵢₙ can be from 1 to 1.05/1.1/1.2/1.3/1.5/2/3. In some embodiments, the above description about we and lₑ may be applied to FIGS. 1B, 1C and 1D, and the description about we may be applied to FIGS. 1F and 1H.

Acoustic wave devices 200a-200n illustrate apodization edges each having a linear shape, e.g., extending as a straight line in the x-direction. The linear shape may extend consistently or intermittently in the x-direction. Acoustic wave device 200a include a first edge region 212A and a second edge region 212B, each being a wave apodization edge as described above and extending in the x-direction. In acoustic wave device 200a, first edge region 212A and second edge region 212B may be located in a center region (referring back to the description of FIG. 1J). In the center region, overlap is formed between first electrode fingers and second electrode fingers. Each of first edge region 212A and second edge region 212B may be between first apodization edge 116A and second apodization edge 116B. First edge region 212A and second edge region 212B may extend in the x-direction in interdigital electrode structure 202, but not extend in reflectors 126. In various embodiments, first edge region 212A and second edge region 212B may or may not be symmetric about middle line 240 of interdigital electrode structure 202. Acoustic wave device 200a shows a configuration in which first edge region 212A and second edge region 212B symmetric about middle line 240, and are each closer to the respective apodization edge than to middle line 240 in the y-direction. Acoustic wave device 200b shows a configuration in which first edge region 212A and second edge region 212B are symmetric to middle line 240, and are each closer to middle line 240 than to the respective apodization edge. Acoustic wave device 200c shows a configuration in which first edge region 212A and second edge region 212B are in the center region but are not symmetric about middle line 240.

In FIG. 2B, acoustic wave device 200d illustrates a configuration in which first edge region 212A and second edge region 212B are each located in a peripheral region (referring back to the description of FIG. 1J. In some embodiments, first edge region 212A is located in the peripheral region between gaps 114B and first busbar 104A, and second edge region 212B is located in the peripheral region between gaps 114A and second busbar 104B.

Different from acoustic wave devices 200a-200c, in acoustic wave device 200e, first edge region 212A and second edge region 212B may each be located in an apodized region (referring back to the description of FIG. 1J). In some embodiments, in the y-direction, first edge region 212A is between a first portion of first apodization edge 116A and a second portion of the first apodization edge 116A, and second edge region 212B is between a first portion of second apodization edge 116A and a second portion of the second apodization edge 116A. In other words, first edge region 212A and second edge region 212B each cross with the respective apodization edge in the x-direction.

FIG. 2C illustrates acoustic wave devices 200f and 200g each includes a single edge region 212. Edge region 212 may be located in different positions in interdigital electrode structure 202. For example, edge region 212 may be aligned with middle line 240 (e.g., in acoustic wave device 200f) or may be deviated from middle line 240 in the center region (e.g., in acoustic wave device 200g). In various embodiments, although not shown, edge region 212 may be located in an apodized region (similar to edge regions 212A or 212B In acoustic wave device 200e) or may be located in an inactive region (similar to edge regions 212A or 212B in acoustic wave device 200d).

FIG. 2D illustrates an acoustic wave device 200h that includes more than two edge regions. As an example, acoustic wave device 200h includes four edge regions 212A, 212B, 212C, and 212D extending in the x-direction. The four edge regions 212A-212D may be non-overlapping with one another and may be located at any suitable positions in interdigital electrode structure 202 to change the transverse SAW amplitude profile to achieve a better transverse mode suppression. In some embodiments, edge regions 212A and 212B may be symmetric about middle line 240, and edge regions 212C and 212D may be symmetric about middle line 240. In various embodiments, one or more of edge regions 212A-212D may all be located in the center region (referred to the description of acoustic wave devices 200a-200c), in an apodized region (referred to the description of acoustic wave devices 200e), and/or in a peripheral region (referred to the description of acoustic wave devices 200d). In an example, all four edge regions 212A-212D may be located in the center region.

FIGS. 2E and 2F illustrate an edge region extending partially in interdigital electrode structure 202 in the x-direction. Acoustic wave device 200i includes a first edge region 212A and a second edge region 212B each only extend in the middle part of interdigital electrode structure 202 in the x-direction. The ends of each edge region may not reach the edge/boundary of interdigital electrode structure 202. For example, a distance D1 between an end of an edge region (e.g., 212A or 212B) and the closest edge of interdigital electrode structure 202 may be between about 5% and about 40% of the length of interdigital electrode structure 202 in the x-direction. In some embodiments, first edge region 212A and second edge region 212B are symmetric about middle line 240 and may each be located in the center region of interdigital electrode structure 202. In various embodiments, first edge region 212A and second edge region 212B may or may not be symmetric about middle line 240, and may each be located in an apodized region (referred to the description of acoustic wave devices 200e), or in a peripheral region (referred to the description of acoustic wave devices 200d).

Acoustic wave devices 200j, 200k, and 200l each includes a first edge region 212A and a second edge region 212B each having an intermittent configuration. As shown in FIG. 2E, in acoustic wave device 200j, first edge region 212A includes a first portion 212A1 and a second portion 212A2, and second edge region 212B includes a first portion 212B1 and a second portion 212B2. First portion 212A1 and second portion 212A2 may be aligned in the y-direction, and first portion 212B1 and second portion 212B2 may be aligned in the y-direction. First portion 212A1 and second portion 212A2 may be disconnected at a middle part of interdigital electrode structure 202, and first portion 212B1 and second portion 212B2 may be disconnected at the middle part of interdigital electrode structure 202. In some embodiments, a distance D2 between two portions of the same edge region is between about 5% and about 80% of the length of interdigital electrode structure 202 in the x-direction. In some embodiments, first edge portion 212A and second edge portion 212B are symmetric about middle line 240 and may each be located in the center region of interdigital electrode structure 202. In various embodiments, first edge region 212A and second edge region 212B may or may not be symmetric about middle line 240, and may each be located in an apodized region (referred to the description of acoustic wave devices 200e), or in a peripheral region (referred to the description of acoustic wave devices 200d).

In acoustic wave device 200k, first edge region 212A includes more than two portions such as a first portion 212A1, a second portion 212A2, a third portion 212A3, a fourth portion 212A4, and a fifth portion 212A5; and second edge region 212B includes more than two portions such as a first portion 212B1, a second portion 212B2, a third portion 212B3, a fourth portion 212B4, and a fifth portion 212B5. All the portions of the same apodization edge may be disconnected from one another, and may be aligned in the y-direction. In some embodiments, a distance D3 between adjacent two portions of the same edge region is between about 5% and about 25% of the length of interdigital electrode structure 202 in the x-direction. In some embodiments, first edge region 212A and second edge region 212B are symmetric about middle line 240 and may each be located in the center region of interdigital electrode structure 202. In various embodiments, first edge region 212A and second edge region 212B may or may not be symmetric about middle line 240, and may each be located in an apodized region (referred to the description of acoustic wave devices 200e), or in a peripheral region (referred to the description of acoustic wave devices 200d).

In acoustic wave device 200l, first edge region 212A includes a first portion 212A1, a second portion 212A2, a third portion 212A3, a fourth portion 212A4, and a fifth portion 212A5; and second edge region 212B includes a first portion 212B1, a second portion 212B2, a third portion 212B3, a fourth portion 212B4, and a fifth portion 212B5. Different from acoustic wave device 200k, at least two portions of the same apodization edge may not be aligned with each other in the y-direction. For example, the portions of the same apodization edge may have a staggered configuration. In some embodiments, a distance D4 between adjacent two portions of the same edge region is between about 5% and about 25% of the length of interdigital electrode structure 202 in the x-direction. In some embodiments, first edge region 212A and second edge region 212B are symmetric about middle line 240 and may each be located in the center region of interdigital electrode structure 202. In other embodiments, first edge region 212A and second edge region 212B may or may not be symmetric about middle line 240, and may each be partially or fully located in an apodized region (referred to the description of acoustic wave devices 200e), or in a peripheral region (referred to the description of acoustic wave devices 200d). For example, one or more portions of the same edge region may be located in the center region, one or more portions of the same edge region may be located in the apodized region, and/or one or more portions of the same edge region may be located in the peripheral region. In some embodiments, in the y-direction, a distance D5 between a pair of symmetrical portions (e.g., 212A1 and 212B1, 212A2 and 212B2, 212A3 and 212B3, 212A4 and 212B4, or 212A5 and 212B5) is different a distance D6 between another pair of symmetrical portions.

FIG. 2G illustrates acoustic wave devices 200m and 200n each includes at least an edge region extending in the respective interdigital electrode structure 202 and at least one of the reflectors 126. Acoustic wave devices 200m and 200n may be different from acoustic wave device 200a such that, at least one of first edge region 212A and second edge region 212B extends through interdigital electrode structure 202 and into at least one of reflectors 126. For example, at least one of first edge region 212A and second edge region 212B extends through interdigital electrode structure 202 and into both reflectors 126. The at least one of first edge region 212A and second edge region 212B may extend through interdigital electrode structure 202, and extend partially (e.g., in acoustic wave device 200n) or fully (e.g., in acoustic wave device 200m) in both reflectors 126. In some embodiments, both of first edge region 212A and second edge region 212B extend through interdigital electrode structure 202, and extend fully in both reflectors 126.

As shown in FIGS. 2H and 2I, acoustic wave devices 200o-200r illustrate edge regions having non-linear shapes, e.g., extending as a curve in the x-direction. It should be noted that, although the edge regions shown in FIGS. 2H and 2I are located in the center region, part or the entirety of an edge region may also be located in an apodized region and/or a peripheral region, referring back to the description of FIG. 2B. Detailed description is not repeated herein. In some embodiments, first edge region 212A and a second edge region 212B, in acoustic wave devices 200o-200r, may be symmetric about middle line 240. Acoustic wave device 2000 may include a first edge region 212A and a second edge region 212B each having a random shape in the x-direction. Acoustic wave device 200p may include a first edge region 212A and a second edge region 212B each having a concave shape towards busbars in the y-direction. Acoustic wave device 200q may include a first edge region 212A and a second edge region 212B each having a convex shape towards busbars in the y-direction. Acoustic wave device 200r may include a first edge region 212A and a second edge region 212B each having a concave shape towards busbars in the y-direction and having contact at middle line 240. In acoustic wave devices 200o-200r, the apodization edges do not extend in reflectors 126.

FIG. 2J illustrates an acoustic wave device 200s that includes a first edge region 212A and a second edge region 212B, each with a shape of a broken line. First edge region 212A includes a first portion 212A1 and a second portion 212A2 extending in different directions and connected at a central line 241 of interdigital electrode structure 202. Central line 241 may extend in the y-direction and may be located at the center position (e.g., in the x-direction) of interdigital electrode structure 202. Second edge region 212B includes a first portion 212B1 and a second portion 212B2 extending in different directions and connected at central line 241. First edge region 212A and second edge region 212B may be symmetric about middle line 240, first portion 212A1 and second portion 212A2 may be symmetric about central line 241, and first portion 212B1 and second portion 212B2 may be symmetric about central line 241. In some embodiments, a distance D7 between first edge region 212A and second edge region 212B decreases towards central line 241. In some embodiments, part or the entirety of an edge region may also be located in an apodized region, a center region, and/or a peripheral region, referring back to the description of FIG. 2B.

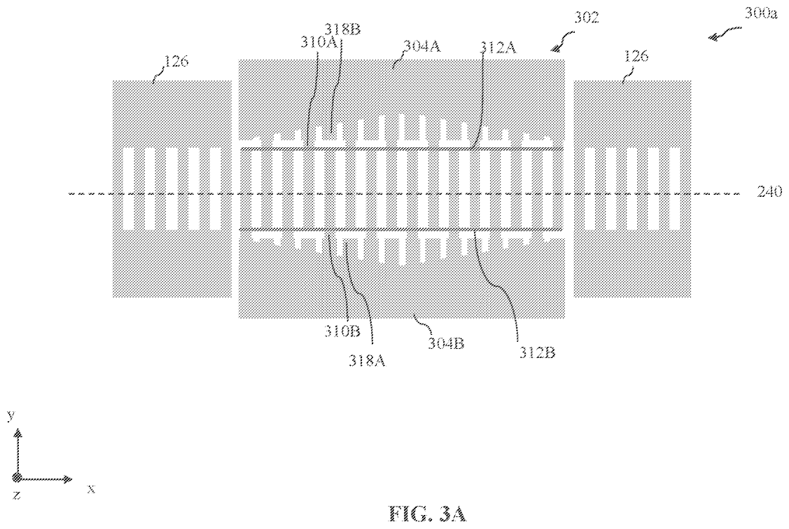

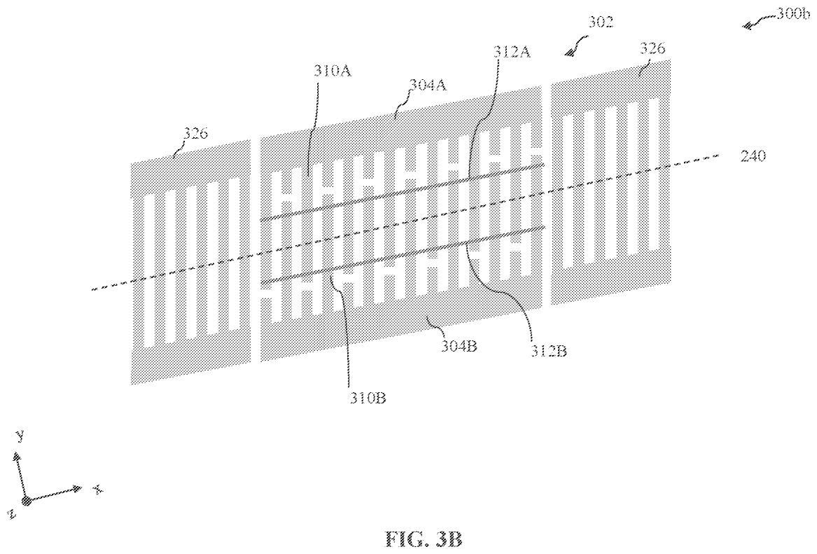

FIGS. 3A-3C illustrate other acoustic wave devices with edge regions, according to some embodiments. For ease of illustration, piezoelectric layer is not shown in the figures. FIG. 3A illustrates an acoustic wave device 300a with dummy electrodes apodization (“Suppression of Spurious Responses for Ultra-Wideband and Low-Loss SAW Ladder Filter on a Cu-grating/15° YX—LiNbO3 Structure”, 2006 IEEE Ultrasonics Symp., pp 1874-1877| by Y. Tanaka, etc.). Acoustic wave device 300a presents a transducer where the position of gaps (e.g., between dummy electrodes and respective electrode fingers) are constant while the aperture changes in the transducer. As shown in FIG. 3A, in interdigital electrode structure 302, first dummy electrodes 318A, extending from second busbar 304B, may be apodized in the y-direction; and second dummy electrodes 318B, extending from first busbar 304A, may be apodized in the y-direction. The gaps between first electrode fingers 310A and first dummy electrodes 318A may have the same position in the y-direction, and the gaps between second electrode fingers 310B and second dummy electrodes 318B may have the same position in the y-direction. Acoustic wave device 300a may include one or more edge regions, e.g., edge regions 312A and 312B. The positions of edge regions 312A and 312B may be referred to the various configurations disclosed in FIGS. 2A-2J, and the details are not repeated. In some embodiments, edge portions 312A and 312B are located in the center region of interdigital electrode structure 302, and may be symmetric about middle line 240.

FIG. 3B illustrates an acoustic wave device 300b having an interdigital electrode structure 302 with slanted apodization, which was discussed in U.S. Pat. No. 11,095,266 B2. First busbar 304A and second busbar 304B may extend in parallel in the x-direction. First electrode fingers 310A may extend obliquely towards second busbar 304B, and second electrode fingers 310B may extend obliquely towards first busbar 304A. First electrode fingers 310A and second electrode fingers 310B may be parallel to each other. Acoustic wave device 300b may include one or more edge regions, e.g., edge regions 312A and 312B. The positions of edge regions 312A and 312B may be referred to the various configurations disclosed in FIGS. 2A-2J, and the details are not repeated. In some embodiments, edge portions 312A and 312B are located in the center region of interdigital electrode structure 302, and may be symmetric about middle line 240 (which extends in the x-direction).

FIG. 3C illustrates an acoustic wave device 300c having an interdigital electrode structure 302 with non-repeated random shape apodization. The apodization edges of interdigital electrode structure 302 may each follow a random curve, such that the lengths of the electrode fingers and respective dummy electrodes are random in the y-direction. Acoustic wave device 300c may include one or more edge regions, e.g., edge regions 312A and 312B. The positions of edge regions 312A and 312B may be referred to the various configurations disclosed in FIGS. 2A-2J, and the details are not repeated. In some embodiments, edge portions 312A and 312B are located in the center region of interdigital electrode structure 302, and may be symmetric about middle line 240 (which extends in the x-direction).

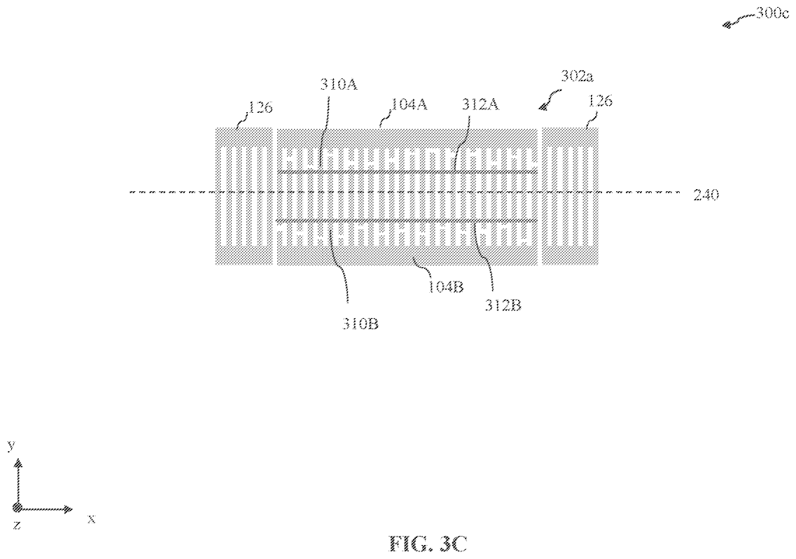

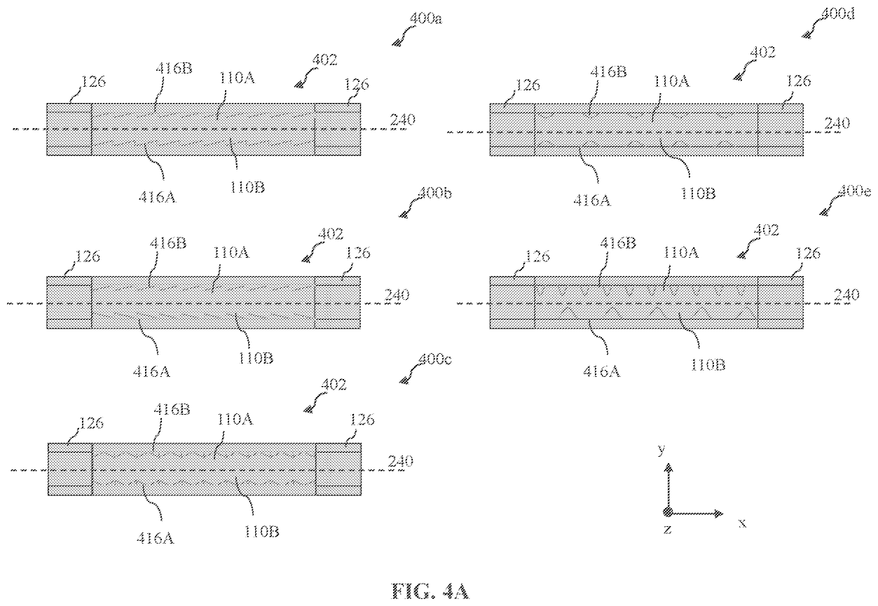

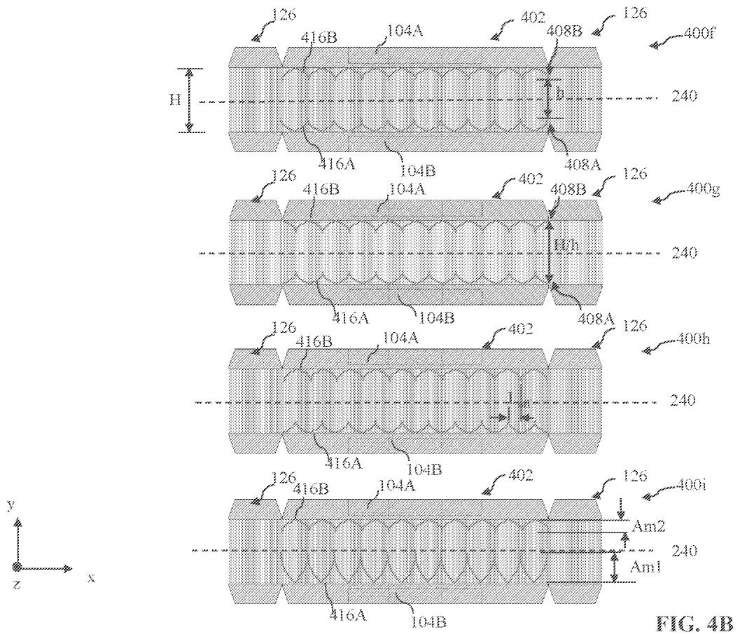

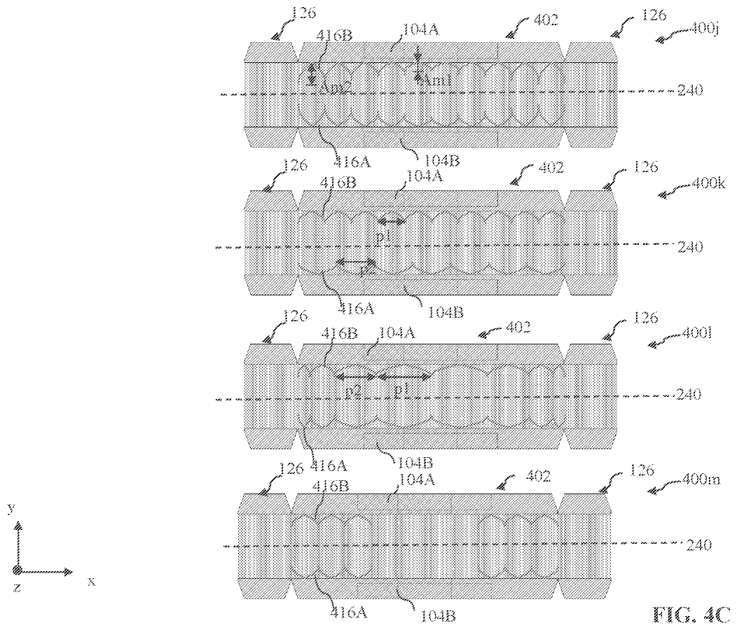

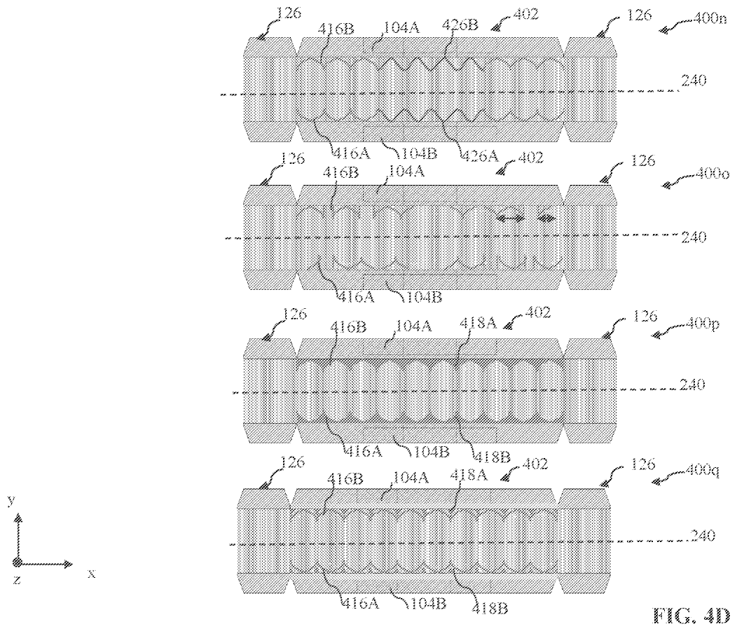

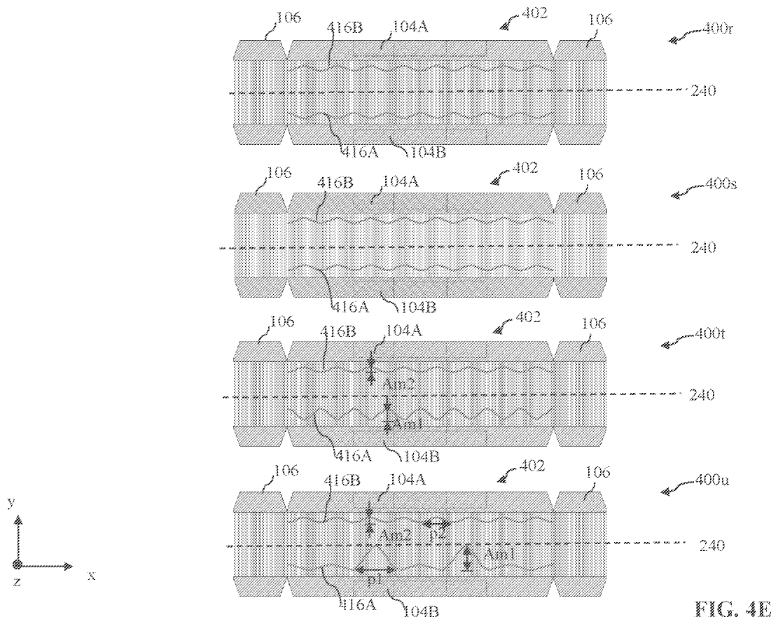

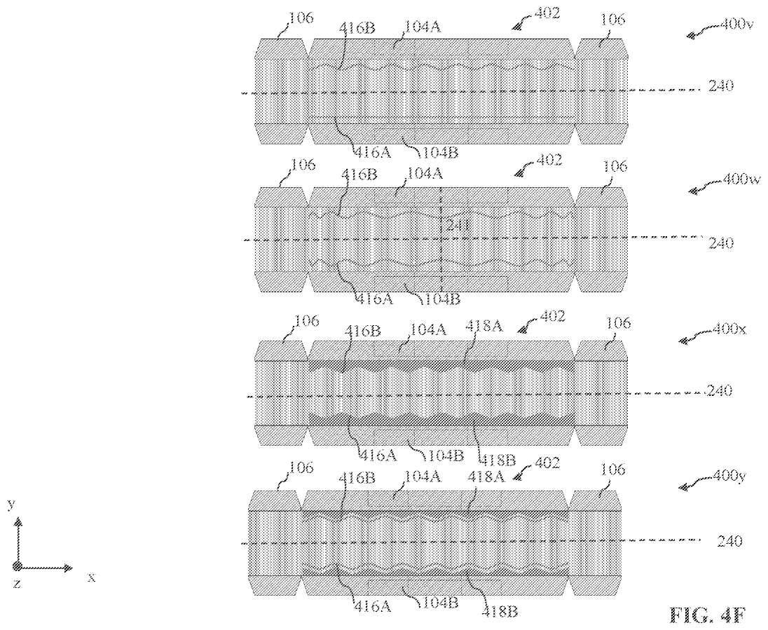

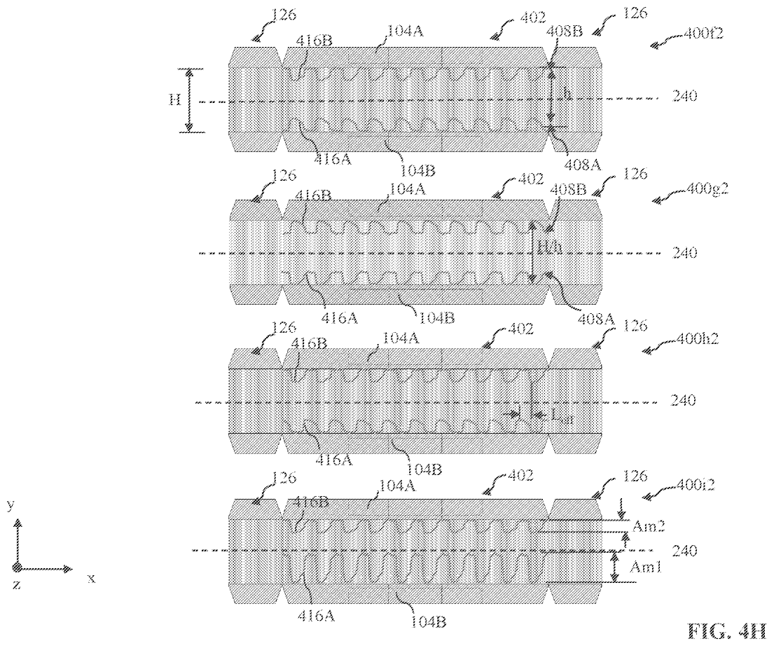

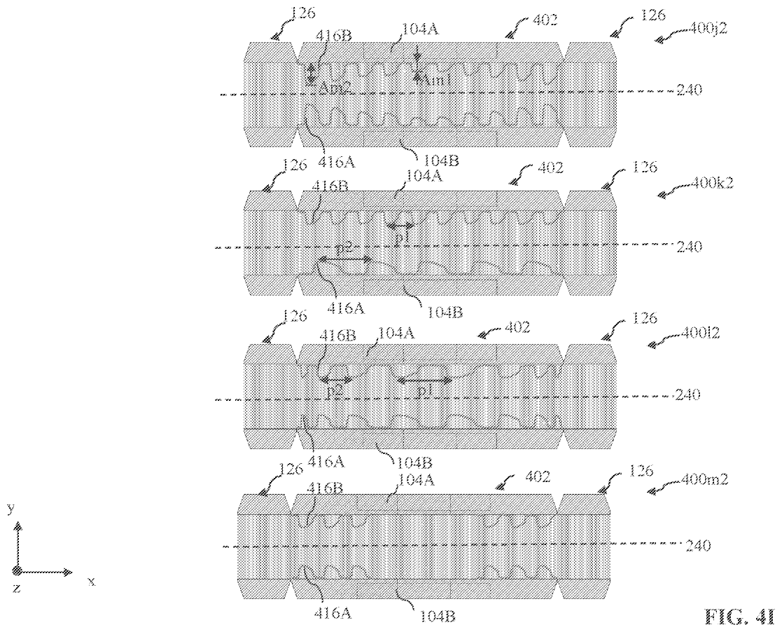

FIGS. 4A-4F illustrate various configurations of apodization edges that can be employed in an acoustic wave device of trapezoidal mode, according to some embodiments. Each of the acoustic wave devices may include a piezoelectric layer (not shown), and an interdigital electrode structure 402 and a pair of reflectors 126. Interdigital electrode structure 402 may be between the reflectors 126. Each of the acoustic wave devices may be apodized with a first apodization edge 416A and a second apodization edge 416B. For example, acoustic wave device 400a illustrates an interdigital electrode structure 402 that includes a plurality of first electrode fingers 110A and second electrode fingers 110B, arranged interweavingly in the x-direction. First electrode fingers 110A and second electrode fingers 110B may be apodized by a first apodization edge 416A and a second apodization edge 416B, respectively. First apodization edge 416A and second apodization edge 416B may each have a saw shape and are not symmetric about middle line 240. Different from acoustic wave device 400a, in acoustic wave device 400b, first electrode fingers 110A and second electrode fingers 110B may be apodized by a first apodization edge 416A and a second apodization edge 416B that are saw shaped and are symmetric about middle line 240. In acoustic wave device 400c, first electrode fingers 110A and second electrode fingers 110B may be apodized by a first apodization edge 416A and a second apodization edge 416B that each includes a plurality of triangular shapes. In acoustic wave device 400d and 400e, first electrode fingers 110A and second electrode fingers 110B may be apodized by a first apodization edge 416A and a second apodization edge 416B that each includes a plurality of intermittent waves. In some embodiments, first apodization edge 416A and second apodization edge 416B are symmetric about middle line 240 (e.g., in acoustic wave device 400d). In some embodiments, first apodization edge 416A and second apodization edge 416B are not symmetric about middle line 240 (e.g., in acoustic wave device 400e). For example, the waves in first apodization edge 416A and second apodization edge 416B may have different numbers of periods, different amplitudes, etc.

In acoustic wave devices 400f-400q, first apodization edge 416A and second apodization edge 416B may each be created based on the modified arccosine function with non-zero

$${L}_{omin} : y = \pm ( {L}_{omin} + ( \frac{{\{ arccos ( x ) \}}^{b} - {\{ arccos ( {x}_{u} ) \}}^{b}}{{\{ arccos ( {x}_{l} ) \}}^{b} - {\{ arccos ( {x}_{u} ) \}}^{b}} ) \times ( 1 - {L}_{omin} ) ) ,$$

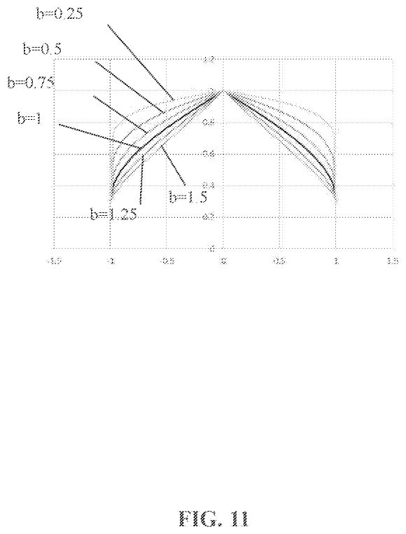

using chosen parameters such as b values. FIG. 11 illustrates a plot of the modified arccosine function at −1≤x≤1, with different b values. In some embodiments, first apodization edge 416A and second apodization edge 416B may each be created based on an arccosine function with non-zero

$${L}_{omin} : y = \pm \{ {L}_{omin} + \frac{arccos \vert x \vert}{arccos ( 0 )} \times ( 1 - {L}_{omin} ) \} , at - 1 \leq x \leq 1.$$

For example, the lower limit of the normalized position value x (xₗ) may be between about −0.5 and 0.5, and the upper limit of the normalized position value x (xᵤ) may be between about 0.75 and about 1. For example, the lower limit of the normalized position value may be −0.5, −0.4, −0.2, 0, 0.2, 0.4, and 0.5, and the upper limit of the normalized position value may be about 0.75, 0.8, 0.9, and 1. In various embodiments, b may be between about 0.5 and about 1.5. For example, b may be 0.5, 0.6, 0.75, 0.9, 1, 1.2, 1.35, and 1.5. In some embodiments, b may be between about 0.7 and about 1.25. In various embodiments, the full period with different shapes (i.e., b value) may repeat in the x-direction to form the arccosine edges with multiple periods to form different arccosine apodization edges. In some embodiments, when b is 1, y is also referred to as a regular arccosine function. Each of the acoustic wave device may include a first busbar 104A and a second busbar 104B, a plurality of first electrode fingers extending from first busbar 104A and a plurality of second electrode fingers extending from second busbar 104B. Detailed description of the acoustic wave device may be referred to that of acoustic wave device 100, and is not repeated herein.

In various embodiments, the apodization edge or curve may not strictly follow a function. For example, for a x value (e.g., a position) on the x-direction, the corresponding function value (e.g., y value) may be a value located in a range from the value calculated from the apodization function. Accordingly, one or more electrode fingers (e.g., first electrode finger 110A and/or second electrode finger 110B) and/or one or more dummy electrodes (e.g., first dummy electrodes 118A and/or second dummy electrodes 118B) may not strictly follow the function the describes the apodization edge, and may deviate away from the respective function within a distance range. Accordingly, the length of the respective dummy electrode may vary such that the dimension of the gap (e.g., gap 114A and/or gap 114B) between the dummy electrode and the respective electrode finger may be unchanged. In some embodiments, a distance between one of an electrode finger (e.g., first electrode finger 110A or second electrode finger 110B) and the respective periodic apodization function (e.g., arccosine function or the modified arccosine function) is less than a first predetermined percentage of an amplitude of the periodic apodization function in the y-direction (e.g., Am). In some embodiments, a distance between a dummy electrode (e.g., first dummy electrode 118A or second dummy electrode 118B) and the respective periodic apodization function is less than a second predetermined percentage of the amplitude of the periodic apodization function in the y-direction. In various embodiments, the first percentage and the second percentage may each be equal to or less than 30%, such as 30%, 25%, 20%, 15%, 10%, etc.

As shown in FIG. 4B, acoustic wave device 400f has a “narrow end” configuration. First apodization edge 416A and second apodization edge 416B may be symmetric about middle line 240. Each period may have a same length in the x-direction. First apodization edge 416A and second apodization edge 416B may have the same amplitudes in the y-direction. At a boundary of interdigital electrode structure 402, an end 408A of first apodization edge 416A and an end 408B of second apodization edge 416B may aligned with each other in the y-direction. A distance h between end 408A and end 408B may be less than a distance H between first busbar 104A and second busbar 104B.

Acoustic wave device 400g has a “wide end” configuration. First apodization edge 416A and second apodization edge 416B may be symmetric about middle line 240. Each period may have a same length in the x-direction. First apodization edge 416A and second apodization edge 416B may have the same amplitudes in the y-direction. At a boundary of interdigital electrode structure 402, distance h between end 408A and end 408B may be the same as distance H between first busbar 104A and second busbar 104B.

Acoustic wave device 400h has an “asymmetric” configuration. Each period may have a same length in the x-direction. First apodization edge 416A and second apodization edge 416B may have the same amplitudes in the y-direction. First apodization edge 416A and second apodization edge 416B may not be symmetric about middle line 240. For example, a period of first apodization edge 416A and a period of second apodization edge 416B may have an offset L_{off} in the x-direction. For example, L_{off} may be the distance between adjacent peaks of first apodization edge 416A and second apodization edge 416B. In some embodiments, L_{off} is less than one period. For example, L_{off} may be a half period.

Acoustic wave device 400i has a “different amplitude” configuration. First apodization edge 416A and second apodization edge 416B may not be symmetric about middle line 240. Each period may have a same length in the x-direction. First apodization edge 416A and second apodization edge 416B may have different amplitudes in the y-direction. For example, apodization edge 416A may have a wave length of Am1, and apodization edge 416B may have a wavelength of Am2, Am1 being different from Am2.

As shown in FIG. 4C, acoustic wave device 400j has a “different amplitudes in x-direction” configuration. Each period may have a same length in the x-direction. First apodization edge 416A and second apodization edge 416B may each have varying amplitudes in the x-direction. First apodization edge 416A and second apodization edge 416B may be symmetric about middle line 240. For example, first apodization edge 416A (or second apodization edge 416B may have a first amplitude Am1 for one period, and have another amplitude Am2 for another period, Am1 being different from Am2. The two periods may be adjacent to each other or may be separated by one or more periods. In some embodiments, first apodization edge 416A (or second apodization edge 416B) may have smaller amplitude(s) in the center of interdigital electrode structure 402, and the amplitude(s) may increase towards the boundaries.

Acoustic wave device 400k has an “different number of periods” configuration. Each period of the respective apodization edge may have a same length in the x-direction, and each apodization edge may include a different number of periods. First apodization edge 416A and second apodization edge 416B may have a different number of periods in the x-direction, and may not be symmetric about middle line 240. For example, the period of first apodization edge 416A may have a length of p2, and the period of second apodization edge 416B may have a length of p1, p1 being different from p2.

Acoustic wave device 400l has an “different periods in x-direction” configuration. One or more periods of the same apodization edge may have different lengths in the x-direction. First apodization edge 416A and second apodization edge 416B may each have varying period lengths in the x-direction. First apodization edge 416A and second apodization edge 416B may be symmetric about middle line 240. For example, first apodization edge 416A (or second apodization edge 416B may have a first length p1 for one period, and have another length p2 for another period, p1 being different from p2. The two periods may be adjacent to each other or may be separated by one or more periods. In some embodiments, a period of first apodization edge 416A (or second apodization edge 416B) may have longer length in the center of interdigital electrode structure 402, and the length may increase towards the boundaries.

Acoustic wave device 400m has a “partial apodization” configuration. First apodization edge 416A and second apodization edge 416B may be symmetric about middle line 240. Each period may have a same length in the x-direction. First apodization edge 416A and second apodization edge 416B may have the same amplitudes in the y-direction. Each of first apodization edge 416A and second apodization edge 416B may apodize part of the electrode fingers, with the rest of the electrode fingers unapodized. For example, first apodization edge 416A (or second apodization edge 416B) may each extend in part of interdigital electrode structure 402 in the x-direction, and may not extend in the rest of the interdigital electrode structure 402. As an example, each of first apodization edge 416A and second apodization edge 416B may include two portions, respectively distributed on the two sides of interdigital electrode structure 402, leaving the center portion of the interdigital electrode structure 402 unapodized. Each portion may include at least two periods.

As shown in FIG. 4D, acoustic wave device 400n has a “partially different apodization” configuration. Different from acoustic wave device 400m, acoustic wave device 400i is also apodized with apodization edges different from first apodization edge 416A and second apodization edge 416B. For example, interdigital electrode structure 402 may be apodized with a first non-arccosine apodization edge 426A between the two portions of first apodization edge 416A, and a second non-arccosine apodization edge 426B between the two portions of second apodization edge 416B. First non-arccosine apodization edge 426A and second non-arccosine apodization edge 426B may be symmetric about middle line 240, and may each be connected to the respective apodization edge. In some embodiments, the non-arccosine apodization edges 426A and 426B each includes a sinusoid curve of one or more periods.

Acoustic wave device 400o has a “intermittent apodization” configuration. First apodization edge 416A and second apodization edge 416B may not be symmetric about middle line 240. First apodization edge 416A and second apodization edge 416B may each have one or mor half periods and/or one or more periods. The half periods and periods may be connected or disconnected, depending on the design. Each period may have a same length in the x-direction. First apodization edge 416A and second apodization edge 416B may have the same amplitudes in the y-direction.

Acoustic wave device 400p has a “metalized dummy/inactive area” configuration. First apodization edge 416A and second apodization edge 416B may be symmetric about middle line 240. Each period may have a same length in the x-direction. First apodization edge 416A and second apodization edge 416B may have the same amplitudes in the y-direction. Different from acoustic wave device 400f, the dummy electrodes extending from the same busbar are connected with metal. For example, adjacent first dummy electrodes (extending from second busbar 104B) and the second electrode finger in between may be metalized to form a metal film. The metal film may not exceed the gaps between the first dummy electrodes and their respective first electrode fingers. Similarly, adjacent second dummy electrodes (extending from first busbar 104A) and the first electrode finger in between may be metalized to form a metal film. The metal film may not exceed the gaps between the second dummy electrodes and their respective second electrode fingers. In some embodiments, all the dummy electrodes extending from the same busbar are metalized together to form metalized dummy areas, shown as 418A and 418B, respectively.

Acoustic wave device 400q has a “partially metalized dummy/inactive area” configuration. First apodization edge 416A and second apodization edge 416B may be symmetric about middle line 240. Each period may have a same length in the x-direction. First apodization edge 416A and second apodization edge 416B may have the same amplitudes in the y-direction. Different from acoustic wave device 400p, the dummy electrodes extending from the same busbar of acoustic wave device 400q are partially metalized. For example, one or more dummy electrodes at a valley of the respective apodization edge 416A/416B are metalized with an adjacent electrode finger. In some embodiments, one or more dummy electrodes at all valleys of the apodization edges 416A and 416B are metallized with an adjacent electrode finger, while dummy electrodes away from the valleys are separated from each other (and any electrode fingers).

Acoustic wave device 400r has a “basic wave” configuration. First apodization edge 416A and second apodization edge 416B may each be a wave apodization edge, and may be symmetric about middle line 240. Each period may have a same length in the x-direction. First apodization edge 416A and second apodization edge 416B may have the same amplitudes in the y-direction.

Acoustic wave device 400s has a “parallel wave” configuration. First apodization edge 416A and second apodization edge 416B may each be a wave apodization edge, and each period may have the same length in the x-direction. Different from acoustic wave device 400r, first apodization edge 416A and second apodization edge 416B may not be parallel about middle line 240. Instead, first apodization edge 416A and second apodization edge 416B may be identical to each other, and may extend in parallel along the x-direction.

Acoustic wave device 400t has a “different wave amplitudes” configuration. First apodization edge 416A and second apodization edge 416B may each be a wave apodization edge, and each period may have the same length in the x-direction. First apodization edge 416A and second apodization edge 416B may have different wave amplitudes. In some embodiments, first apodization edge 416A may have a wave amplitude Am1 and second apodization edge 416B may have a wave amplitude Am2, Am1 being different from Am2.

Acoustic wave device 400u has a “different wave amplitudes and periods” configuration. First apodization edge 416A and second apodization edge 416B may each be a wave apodization edge, and may not be symmetric about middle line 240. Periods of first apodization edge 416A and second apodization edge 416B may have different lengths in the x-direction. First apodization edge 416A and second apodization edge 416B may have different wave amplitudes in the y-direction. In some embodiments, a period of first apodization edge 416A has a length p1 and a period of second apodization edge 416B has a length p2 in the x-direction, p1 being different from p2. In some embodiments, first apodization edge 416A may have a wave amplitude Am1 and second apodization edge 416B may have a wave amplitude Am2, Am1 being different from Am2.

Acoustic wave device 400v has a “one wave” configuration. Only one of first apodization edge 416A and second apodization edge 416B is a wave apodization edge, and first apodization edge 416A and second apodization edge 416B may not be symmetric about middle line 240. In some embodiments, first apodization edge 416A is a straight line extending in the x-direction, while second apodization edge 416B is a wave apodization edge.

Acoustic wave device 400w has a “chirped wave” configuration. First apodization edge 416A and second apodization edge 416B may each be a chirped wave apodization edge, and may be symmetric about middle line 240. The periods of each of first apodization edge 416A and second apodization edge 416B may have varying lengths in the x-direction. For example, the lengths of the periods may increase and then decrease in the x-direction. In some embodiments, first apodization edge 416A and second apodization edge 416B may each be symmetric about central line 241. First apodization edge 416A and second apodization edge 416B may have the same amplitudes in the y-direction.

Acoustic wave device 400x has a “metalized dummy/inactive area” configuration. First apodization edge 416A and second apodization edge 416B may be symmetric about middle line 240. Each period may have a same length in the x-direction. First apodization edge 416A and second apodization edge 416B may have the same amplitudes in the y-direction. Different from acoustic wave device 400r, the dummy electrodes extending from the same busbar are connected with metal. For example, a first dummy electrode (extending from second busbar 104B) and an adjacent second electrode finger may be metalized to form a metal film. In some embodiments, adjacent first dummy electrodes and the second electrode finger in between may be metalized to form a metal film. The metal film may not exceed the gaps between the first dummy electrodes and their respective first electrode fingers. Similarly, a second dummy electrode (extending from first busbar 104A) and an adjacent first electrode finger may be metalized to form a metal film. In some embodiments, adjacent second dummy electrodes and the first electrode finger in between may be metalized to form a metal film. The metal film may not exceed the gaps between the second dummy electrodes and their respective second electrode fingers. In some embodiments, all the dummy electrodes extending from the same busbar are metalized together to form metalized dummy areas, shown as 418A and 418B, respectively.

Acoustic wave device 400y has a “partially metalized dummy/inactive area” configuration. First apodization edge 416A and second apodization edge 416B may be symmetric about middle line 240. Each period may have a same length in the x-direction. First apodization edge 416A and second apodization edge 416B may have the same amplitudes in the y-direction. Different from acoustic wave device 400x, the dummy electrodes extending from the same busbar of acoustic wave device 400y are partially metalized. For example, dummy electrodes may be partially metalized in the y-direction, forming partial metalized dummy areas, shown as 418A and 418B.

FIGS. 4H and 4I show examples of repeated random shape apodizations. In some embodiments, each period of the apodization edge (e.g., 416A and 416B) includes a random shape and may not be described using a simple (or single) function. As shown in FIG. 4H, acoustic wave device 400f2 has a “wide end” configuration. First apodization edge 416A and second apodization edge 416B of acoustic wave device 400f2 may be symmetric about middle line 240. Each period may have a same length in the x-direction. First apodization edge 416A and second apodization edge 416B may have the same amplitudes in the y-direction. At a boundary of interdigital electrode structure 402, an end 408A of first apodization edge 416A and an end 408B of second apodization edge 416B may aligned with each other in the y-direction. A distance between end 408A and end 408B may be equal to a distance H between first busbar 104A and second busbar 104B.

First apodization edge 416A and second apodization edge 416B of acoustic wave device 400g2 may be symmetric about middle line 240. Each period may have a same length in the x-direction. First apodization edge 416A and second apodization edge 416B may have the same amplitudes in the y-direction. At a boundary of interdigital electrode structure 402, distance h between end 408A and end 408B may be the same as distance H between first busbar 104A and second busbar 104B.

Acoustic wave device 400h2 has an “asymmetric” configuration. Each period may have a same length in the x-direction. First apodization edge 416A and second apodization edge 416B may have the same amplitudes in the y-direction. First apodization edge 416A and second apodization edge 416B may not be symmetric about middle line 240. For example, a period of first apodization edge 416A and a period of second apodization edge 416B may have an offset L_{off} in the x-direction. For example, L_{off} may be the distance between adjacent peaks of first apodization edge 416A and second apodization edge 416B. In some embodiments, L_{off} is less than one period. For example, L_{off} may be a half period.

Acoustic wave device 400i2 has a “different amplitude” configuration. First apodization edge 416A and second apodization edge 416B may not be symmetric about middle line 240. Each period may have a same length in the x-direction. First apodization edge 416A and second apodization edge 416B may have different amplitudes in the y-direction. For example, apodization edge 416A may have a wave length of Am1, and apodization edge 416B may have a wavelength of Am2, Am1 being different from Am2.

As shown in FIG. 4I, acoustic wave device 400j2 has an “different amplitudes in x-direction” configuration. Each period may have a same length in the x-direction. First apodization edge 416A and second apodization edge 416B may each have varying amplitudes in the x-direction. First apodization edge 416A and second apodization edge 416B may be symmetric about middle line 240. For example, first apodization edge 416A (or second apodization edge 416B may have a first amplitude Am1 for one period, and have another amplitude Am2 for another period, Am1 being different from Am2. The two periods may be adjacent to each other or may be separated by one or more periods. In some embodiments, first apodization edge 416A (or second apodization edge 416B) may have smaller amplitude(s) in the center of interdigital electrode structure 402, and the amplitude(s) may increase towards the boundaries.

Acoustic wave device 400k2 has an “different number of periods” configuration. Each period of the respective apodization edge may have a same length in the x-direction, and each apodization edge may include a different number of periods. First apodization edge 416A and second apodization edge 416B may have a different number of periods in the x-direction, and may not be symmetric about middle line 240. For example, the period of first apodization edge 416A may have a length of p2, and the period of second apodization edge 416B may have a length of p1, p1 being different from p2.

Acoustic wave device 400l2 has a “different periods in x-direction” configuration. One or more periods of the same apodization edge may have different lengths in the x-direction. First apodization edge 416A and second apodization edge 416B may each have varying period lengths in the x-direction. First apodization edge 416A and second apodization edge 416B may be symmetric about middle line 240. For example, first apodization edge 416A (or second apodization edge 416B may have a first length p1 for one period, and have another length p2 for another period, p1 being different from p2. The two periods may be adjacent to each other or may be separated by one or more periods. In some embodiments, a period of first apodization edge 416A (or second apodization edge 416B) may have longer length in the center of interdigital electrode structure 402, and the length may increase towards the boundaries.

Acoustic wave device 400m2 has a “partial apodization” configuration. First apodization edge 416A and second apodization edge 416B may be symmetric about middle line 240. Each period may have a same length in the x-direction. First apodization edge 416A and second apodization edge 416B may have the same amplitudes in the y-direction. Each of first apodization edge 416A and second apodization edge 416B may apodize part of the electrode fingers, with the rest of the electrode fingers unapodized. For example, first apodization edge 416A (or second apodization edge 416B) may each extend in part of interdigital electrode structure 402 in the x-direction, and may not extend in the rest of the interdigital electrode structure 402. As an example, each of first apodization edge 416A and second apodization edge 416B may include two portions, respectively distributed on the two sides of interdigital electrode structure 402, leaving the center portion of the interdigital electrode structure 402 unapodized. Each portion may include at least two periods.

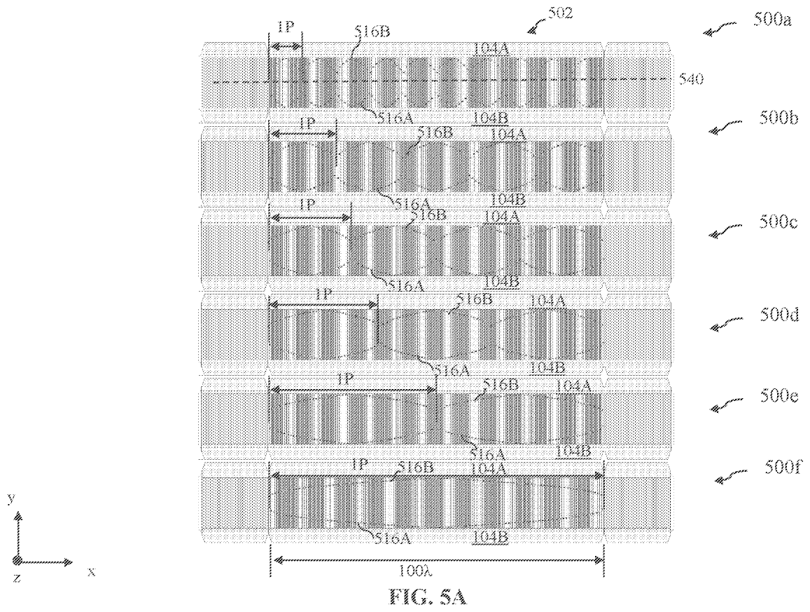

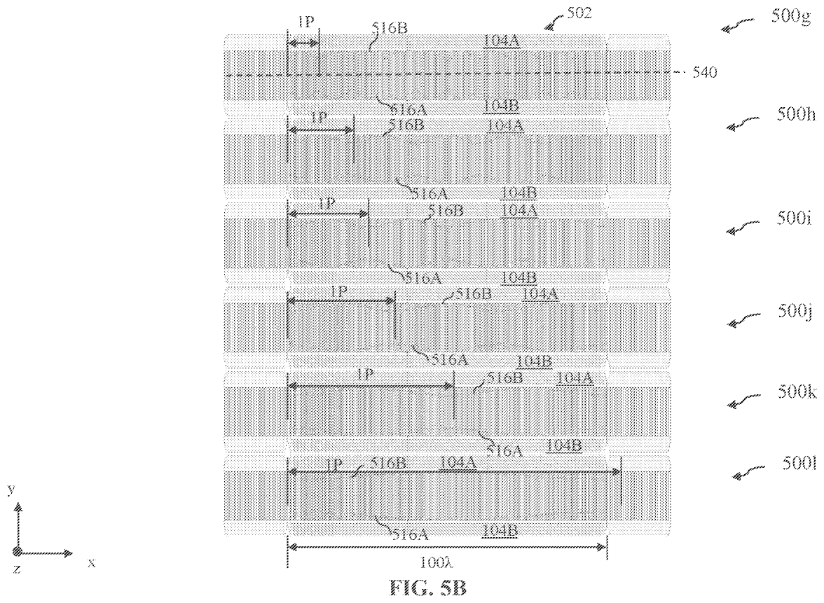

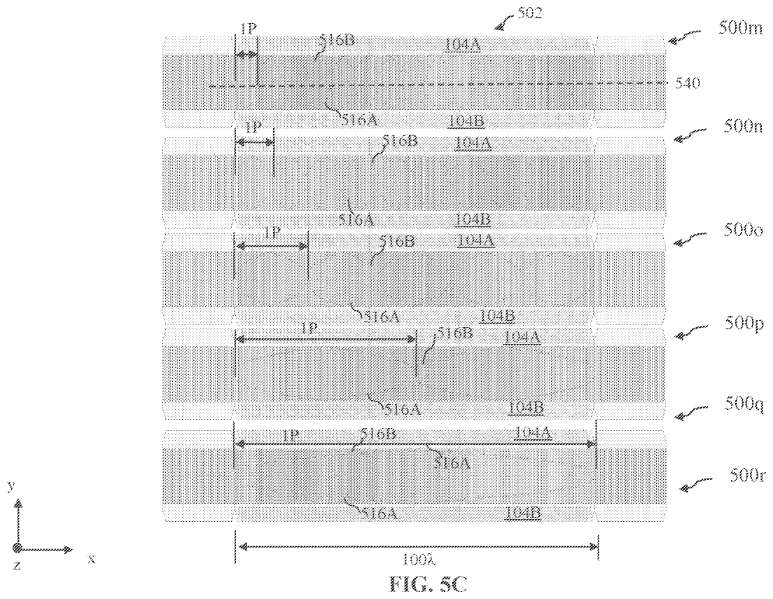

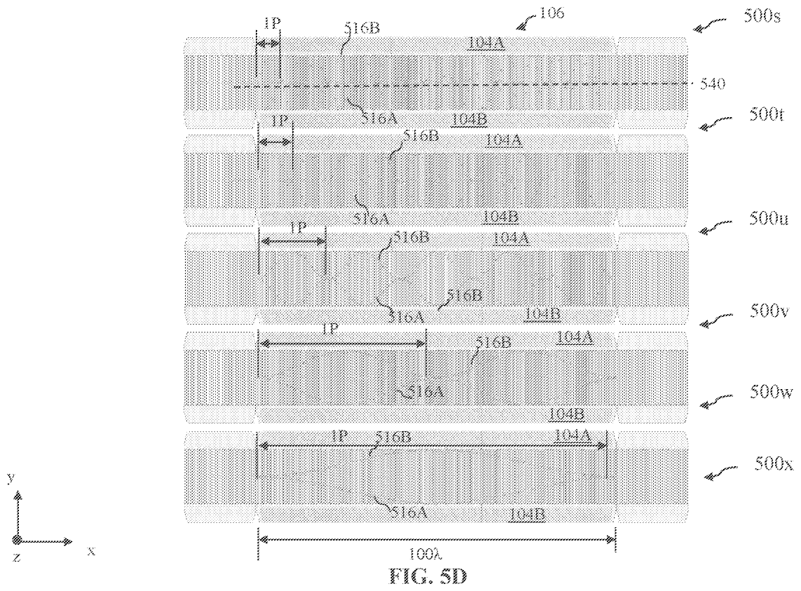

FIGS. 5A-5D each illustrates acoustic wave devices having apodization edges with different numbers of periods in the x-direction, according to some embodiments. Each of the apodization edges may be employed in an acoustic wave device in trapezoidal mode, according to the embodiments of the present disclosure. For ease of illustration, edge regions are not shown in the figures.

In FIG. 5A, an apodization edge may follow a modified arccosine function

$$y = \pm ( {L}_{omin} + ( \frac{{\{ arccos ( x ) \}}^{b} - {\{ arccos ( {x}_{u} ) \}}^{b}}{{\{ arccos ( {x}_{l} ) )}^{b} - {\{ arccos ( {x}_{u} ) \}}^{b}} ) \times ( 1 - {L}_{omin} ) ) , 1 \leq x \leq 1 ,$$

Lₒₘᵢₙ being non-zero, as stated above, and may have a plurality of periods in the x-direction. FIG. 5A illustrates acoustic wave devices 500a, 500b, 500c, 500d, 500e, and 500f. Each of the acoustic wave device may include a first busbar 104A and a second busbar 104B, a plurality of first electrode fingers extending from first busbar 104A and a plurality of second electrode fingers extending from second busbar 104B. The interdigital electrode structure 502 of each acoustic wave device is apodized by a pair of apodization edges. For example, each of these acoustic wave devices is apodized by a first apodization edge 516A and a second apodization edge 516B. In some embodiments, first apodization edge 516A and second apodization edge 516B are symmetric about a middle line 540 of the respective interdigital electrode structure. Detailed description of each acoustic wave device may be referred to that of acoustic wave device 100, and is not repeated herein.

The apodization edges in each of the acoustic wave device may have a different number of periods, each denoted as “1P”. As shown in FIG. 5A, in a distance of 100% in the x-direction, acoustic wave device 500a may have 10 periods, acoustic wave device 500b may have 5 periods, acoustic wave device 500c may have 4 periods, acoustic wave device 500d may have 3 periods, acoustic wave device 500e may have 2 periods, and acoustic wave device 500f may have 1 period. In each acoustic wave device, the periods are identical.

An apodization edge in FIG. 5B may follow the wave function y=±{Lₒₘᵢₙ+(cos x+1)/2×(1−Lₒₘᵢₙ)}, −π≤x≤+π, Lₒₘᵢₙ being non-zero, and may have a plurality of periods in the x-direction. FIG. 5B illustrates acoustic wave devices 500g, 500h, 500i, 500j, 500k, and 500l. In some embodiments, first apodization edge 516A and second apodization edge 516B are symmetric about a middle line 540 of the respective interdigital electrode structure. Detailed description of each acoustic wave device may be referred to that of acoustic wave device 100, and is not repeated herein. The apodization edges in each of the acoustic wave device may have a different number of periods, each denoted as “1P”. As shown in FIG. 5B, in a distance of 100% in the x-direction, acoustic wave device 500g may have 10 periods, acoustic wave device 500h may have 5 periods, acoustic wave device 500i may have 4 periods, acoustic wave device 500j may have 3 periods, acoustic wave device 500k may have 2 periods, and acoustic wave device 500l may have 1 period. In each acoustic wave device, the periods are identical.

FIG. 5C illustrates acoustic wave devices 500m, 500n, 500o, 500p, 500q, and 500r. An apodization edge in FIG. 5C may follow the same modified arccosine function as that of FIG. 5A, but with Lₒₘᵢₙ being zero. The apodization edge may have the same plurality of periods in the x-direction as of FIG. 5A. It should be noted that, because of digitization, the minimum overlap may not appear to be zero in the figures.

FIG. 5D illustrates acoustic wave devices 500s, 500t, 500u, 500v, 500w, and 500x. An apodization edge in FIG. 5D may follow the same wave function as that of FIG. 5B, but with Lₒₘᵢₙ being zero. The apodization edge may have the same plurality of periods in the x-direction as of FIG. 5B.

In various embodiments, first apodization edge 516A and second apodization edge 516B may not be symmetric about middle line 540, referring back to the description of FIGS. 4A-4F. The locations of first apodization edge 516A and second apodization edge 516B should not be limited by the embodiments of the present disclosure.

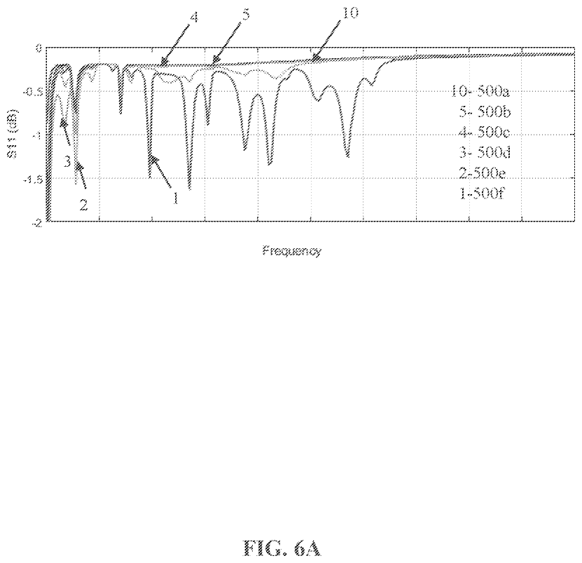

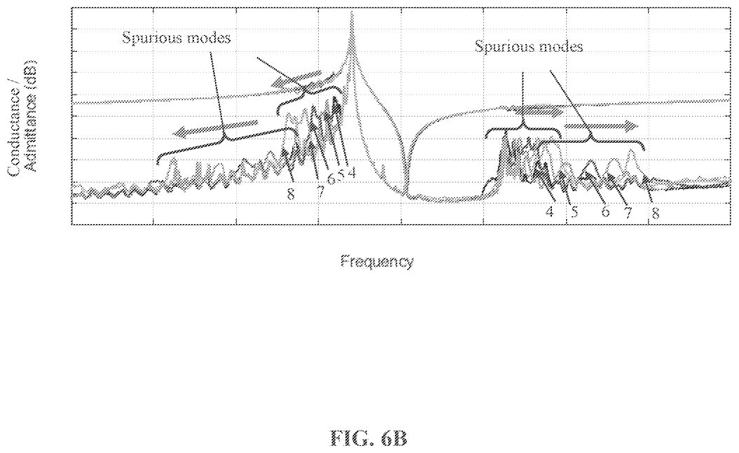

FIG. 6A illustrates a comparison of suppression of transverse modes, S11 (of one port resonator) by different acoustic wave devices 500a-500f. As shown in FIG. 6A, transverse modes are suppressed when the number of periods is at least 3 (or 4, 5, 6, 7, 8) per 100λ, λ being the wavelength of the acoustic wave. For example, when the number of periods is 4, 5, or 10, transverse modes may be suppressed. FIG. 6B illustrates a comparison of spurious frequencies in conductance/admittance of one port resonators by different acoustic wave devices similar to 500a but with different numbers of periods. As shown in FIG. 6B, spurious modes shift in frequency by changing the number of periods. By increasing the number of periods, spurious modes below resonance frequency move down to lower frequency side, and spurious modes above resonance frequency move up to higher frequency side, which is better because spurious modes go further from the resonance frequency and can be avoided from the filter passband if it's a filter application. Depending on the filter application, the minimum period accepted varies, but larger number of periods is better in general to avoid spurious modes.

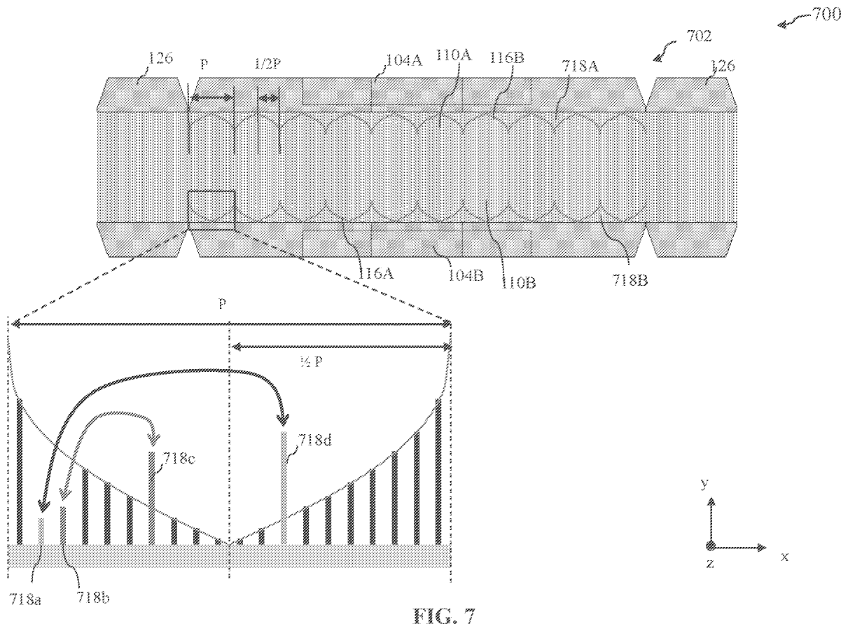

FIG. 7 illustrates a configuration of dummy electrodes in an acoustic wave device 700 with multi-period arccosine apodization, according to some embodiments. Similar to acoustic wave device 100, acoustic wave device 700 includes an interdigital electrode structure 702 and a pair of reflectors 126. Interdigital electrode structure 702 may include first busbar 104A and second busbar 104B, a plurality of first electrode fingers 110A and a plurality of second electrode fingers 110B, and a plurality of first dummy electrodes 718A and a plurality of second dummy electrodes 718B. First electrode fingers 110A and second electrode fingers 110B may be apodized with first apodization edge 716A and second apodization edge 716B, respectively. As an example, first apodization edge 716A and second apodization edge 716B may each be an acrosine apodization edge and described as

$$y = \pm ( {L}_{omin} + ( \frac{{{\{ arccos ( x ) \}}^{b} - \{ arccos ( {x}_{u} ) )}^{b}}{{\{ arccos ( {x}_{l} ) \}}^{b} - {\{ arc cos ( {x}_{u} ) \}}^{b}} ) \times ( 1 - {L}_{omin} ) ) , 1 \leq x \leq 1 ,$$

Lₒₘᵢₙ being non-zero, as stated above (or similar to acoustic wave device 400f). First dummy electrodes 718A may extend from second busbar 104B towards first apodization edge 716A, and second dummy electrodes 718B may extend from first busbar 104A towards second apodization edge 716B.

Different from acoustic wave device 400f, a first dummy electrode at a first position of a busbar may be swapped with a second dummy electrode at a second position of the same busbar. The first and second dummy electrodes may have different lengths in the y-direction. In various embodiments, the first and second dummy electrodes may be in the same period, in the same half period, or in different periods. In such configuration, the length of the electrode fingers aligned with the dummy electrodes (e.g., in the y-direction) may be adjusted accordingly to maintain a gap between the respective electrode and the dummy electrode. For example, as shown in FIG. 7, first dummy electrode 718a may be swapped with first dummy electrode 718d in the same period (but different half periods), and/or first dummy electrode 718b may be swapped with first dummy electrode 718c in the same half period. Accordingly, the first electrode fingers aligned with the first dummy electrodes (e.g., 718a, 718b, and 718c) are also swapped such that the gap between a first dummy electrode and the respective first electrode finger stays unchanged. In another example, first dummy electrodes 718c may be in a different period than first dummy electrode 718b, and/or first dummy electrodes 718a may be in a different period than first dummy electrode 718d. In various embodiments, the number of dummy electrodes in the swap can vary and is not limited to the embodiments of the present disclosure. The second dummy electrodes and respective second electrode fingers can be swapped in a similar way, and the detailed description is not repeated herein.

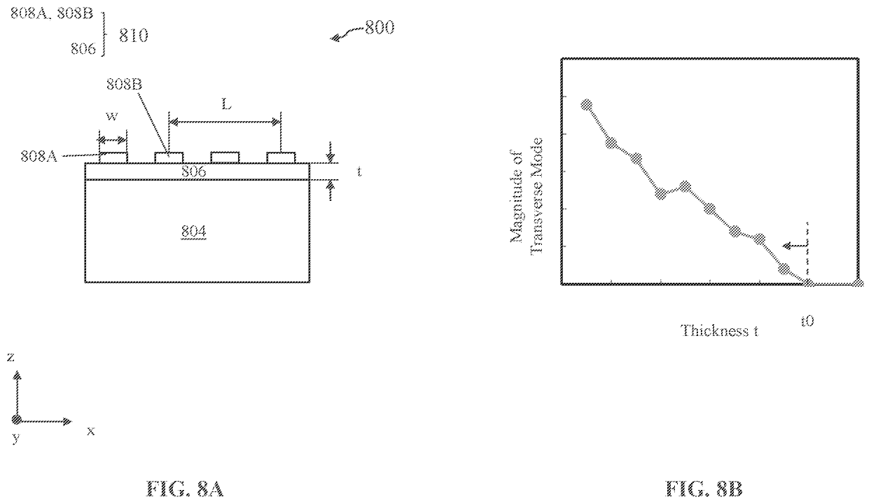

The disclosed acoustic wave device in trapezoidal mode with apodization may be employed in various applications. FIG. 8A illustrates a bonded wafer structure 800 with an acoustic wave device 810 in trapezoidal mode with apodization. In some embodiments, piezoelectric layer 806 includes lithium tantalate (LiTaO) and/or lithium niobate (LiNbO). In some embodiments, substrate 804 includes at least one of silicon, sapphire, quartz, silicon carbide, spinel, ceramics, and/or other insulation/semiconductor materials. A thickness t of piezoelectric layer 806 (e.g., in the z-direction) may be less than t0. As shown in FIG. 8B, when thickness t is less than a threshold thickness value t0 (e.g., typically about 5λ), transverse modes may be observed in the acoustic wave. For example, thickness t may be less than 5λ, 4λ, 3λ, 2λ, λ, etc. To reduce the transverse modes, the disclosed acoustic wave device, e.g., acoustic wave device 810, may be applied on substrate 804. In some embodiments, piezoelectric layer 806 is a piezoelectric substrate, and no additional substrate is needed. The piezoelectric substrate, including a piezoelectric layer, may have sufficient thickness to support the manufacturing and functioning of acoustic wave device 810. For example, the piezoelectric substrate may be a piezoelectric wafer. In some embodiments, piezoelectric layer 806 is a piezoelectric membrane with the thickness less than the wavelength 2 of the acoustic wave. In some embodiments, no additional substrate is formed under piezoelectric membrane.

Acoustic wave device 810 may be any one of the acoustic wave devices of this disclosure (e.g., acoustic wave devices 100, 200a-200s, 300a-300c, 400a-400y, 500a-500x, etc.). Acoustic wave device 810 may include a substrate 804 and a piezoelectric layer 806 disposed on substrate 804. Acoustic wave device 810 may also include a plurality of first electrode fingers 808A and a plurality of second electrode fingers 808B interweavingly disposed on piezoelectric layer 806. A width w of a first electrode finger 808A (or second electrode finger 808B) may be about 0.25λ, λ being the wavelength of the acoustic wave propagating in the electrode fingers. A distance L between adjacent first electrode fingers 808A or between adjacent second electrode fingers 808B may be about λ.

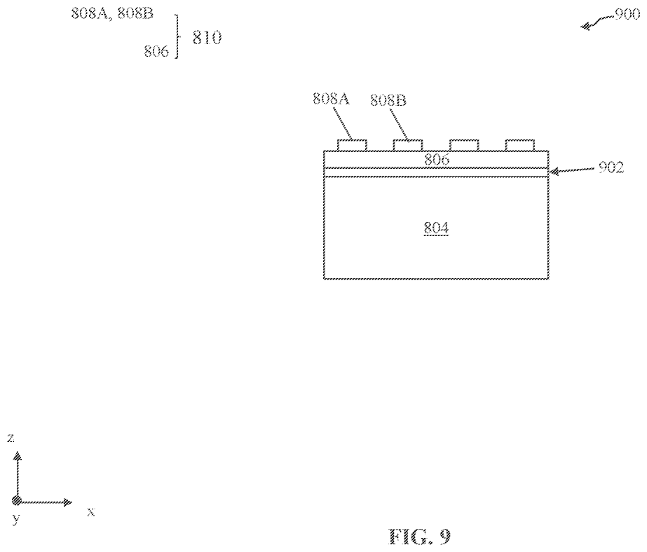

FIG. 9 illustrates a bonded wafer structure 900 with an acoustic wave device 810 in trapezoidal mode with apodization. Different from bonded wafer structure 800, bonded wafer structure 900 includes an intermediate layer 902 between piezoelectric layer 806 and substrate 804. Intermediate layer 902 may include a material that has a positive temperature coefficient of velocity, and can thus compensate the velocity change of the acoustic wave by other layers/materials (e.g., which typically have a negative temperature coefficient of velocity). In some embodiments, intermediate layer 902 includes an insulating material and/or a semiconductor layer, such as silicon oxide (SiO) and/or tantalum oxide (TaₓO_{y}) (SiO₂ and/or Ta₂O₅).

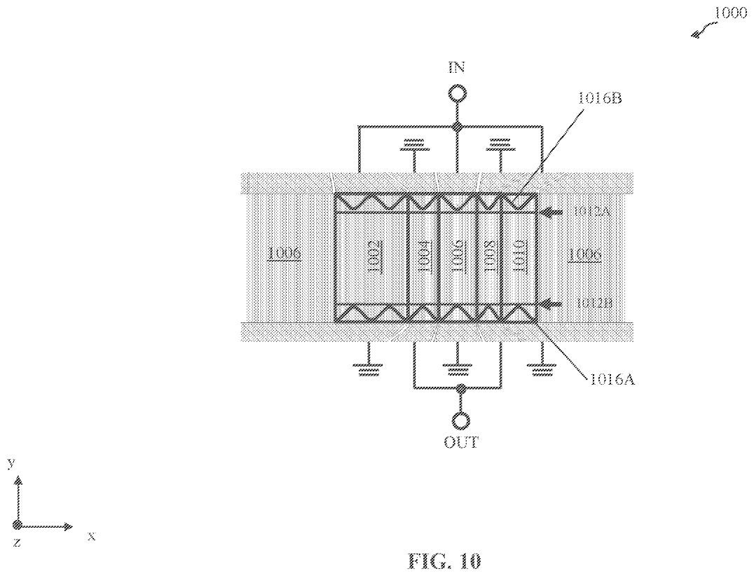

FIG. 10 illustrates a coupled resonator filter 1000 with a plurality of acoustic wave devices in trapezoidal mode with apodization. As shown in FIG. 10, a coupled resonator filter 1000 may include acoustic wave devices 1002, 1004, 1006, 1008, and 1010 (e.g., interdigital transducers) arranged in the x-direction to provide a desired filter response. Adjacent acoustic wave devices may be forwardly biased or reversely biased. As an example, FIG. 10 shows adjacent acoustic wave devices are reversely biased. Each of acoustic wave devices 1002-1010 may be any of the acoustic wave devices of this disclosure (e.g., acoustic wave devices 100, 200a-200s, 300a-300c, 400a-400y, 500a-500x, etc.). For example, acoustic wave devices 1002-1010 may include edge regions 1012A and 1012B, and may be apodized with a respective first apodization edge and a respective second apodization edge. As shown in FIG. 10, acoustic wave devices 1002-1010 may be coupled between an input node IN, an output node OUT, and ground. Acoustic wave devices 1002-1010 may be arranged to be adjacent to one another, and the first apodization edges and the second apodization edges may be respectively connected/aligned together to form a first apodization edge 1016A and a second apodization edge 1016B. In various embodiments, first apodization edge 1016A and second apodization edge 1016B may or may not be continuous along the x-direction. A pair of reflectors 1006 are provided respectively adjacent to acoustic wave device 1002 and acoustic wave device 1010.

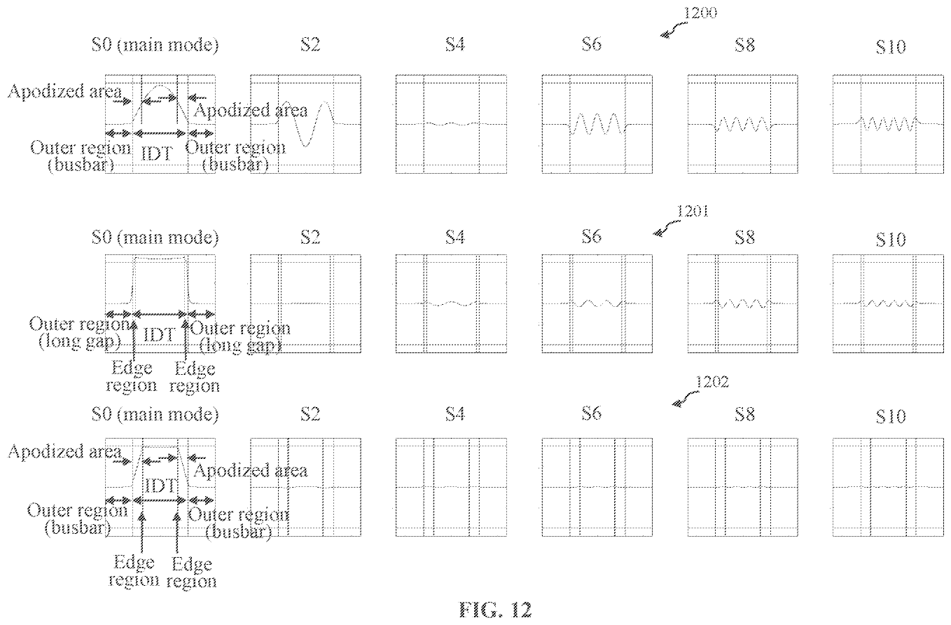

FIG. 12 illustrates simulated mode profiles for acoustic wave devices 1200, 1201, and 1202, according to some embodiments. Acoustic wave device 1200 may include an interdigital electrode structure that is apodized with wave apodization (e.g., similar to the wave apodization edges in acoustic wave device 400r) but without any edge regions. Acoustic wave device 1201 may be in piston mode and may include an interdigital electrode structure that includes a pair of edge regions but without any apodization. The edge regions of acoustic wave device 1201 may be located at the ends of the respective electrode fingers, which is different from acoustic wave device 200a of this disclosure. In some embodiments, the edge regions in acoustic wave device 1201 may be slow regions or fast regions. Acoustic wave device 1202 may be in trapezoidal mode with wave apodization. Acoustic wave device 1202 may include an interdigital electrode structure that includes a pair of edge regions which are located in the interdigital electrode region away from the ends of the respective electrode fingers and are apodized with wave apodization edges (e.g., similar to acoustic wave device 200a). S0 is the main mode, and S2-S10 are transverse modes. S0 of acoustic wave device 1202 has a trapezoidal shape, unlike a piston shape by acoustic wave device 1201, which is in piston mode. This is because the edge regions in acoustic wave device 1202 are located in the interdigital electrode region, instead of at the ends of the respective electrode fingers. Because the mode shape of S0 for acoustic wave device 1202 is trapezoid, the mode shape is referred to as “trapezoidal mode.”

As shown in FIG. 12, as an acoustic wave propagates in the interdigital electrode structure (“IDT”) between two outer regions (may include busbars and long finger-edge-gaps,). In some embodiments, an outer region is an area outside the IDT, and the acoustic wave is not excited there in the outer region. The outer region includes a busbar, a respective dummy electrode area in contact with the busbar and having a width of minimum dummy length (L1 or L2 in FIG. 1J), a gap (e.g., gap 114A or 114B, up to 1 to 2 lambda long) and patterned busbar (there is not a metal in the patterned busbar areas). The acoustic wave may be confined between the two outer regions. The edge portion/region is not on the edge of electrode finger having the closest distance from the outer region.

Acoustic wave device 1200 has large amplitude of transverse modes S2-S10 meaning that acoustic wave device 1200 does not suppress transverse modes very well. Acoustic wave device 1201 has smaller amplitude of transverse modes S2-S10 than acoustic wave device 1200 meaning that acoustic wave device 1201 suppresses transverse mode more than acoustic wave device 1200. Acoustic wave device 1202 has the smallest amplitude of transverse modes S2-S10 of all devices (nearly complete suppression of transverse modes) meaning that acoustic wave device 1202 suppresses transverse modes more than acoustic wave device 1201. The trapezoidal mode changes the transverse mode profile of each higher order transverse mode with the edge regions. The changes in transverse mode profiles in trapezoidal mode significantly help to suppress the transverse modes with apodizations. In other words, the trapezoidal mode improves the efficiency for suppression of transverse modes in apodization by changing the transverse mode profile of each higher order transverse mode. Therefore, the acoustic wave device 1202 can achieve the best transverse mode suppression of all devices in FIG. 12. Because acoustic wave device 1202 have a relatively flat profile, it has more transduction than acoustic wave device 1200, which suggests a higher electromechanical coupling coefficient k² than that of acoustic wave devices 1200.

Those skilled in the art will recognize improvements and modifications to the preferred embodiments of the present disclosure. All such improvements and modifications are considered within the scope of the concepts disclosed herein and the claims that follow.

1. An acoustic wave device, comprising:
a piezoelectric layer; and
an interdigital electrode structure over the piezoelectric layer, the interdigital electrode structure comprising a plurality of first electrode fingers and a plurality of second electrode fingers extending in a width direction, the plurality of first electrode fingers and the plurality of second electrode fingers interleaved with one another along a length direction, the length direction being different from the width direction, wherein:
at least one of the plurality of first electrode fingers or the plurality of second electrode fingers includes an edge portion between two ends of a respective electrode finger, a wave velocity of an acoustic wave propagating in the edge portion along the length direction is different from that outside of the edge portion; and
the at least one of the plurality of first electrode fingers or the plurality of second electrode fingers is apodized with an apodization pattern.

2. The acoustic wave device of claim 1, wherein the edge portion of the at least one of the plurality of first electrode fingers or the plurality of second electrode fingers form an edge region that has one of a straight line, an intermittent line, a staggered intermittent line, a non-linear line, or a broken line.

3. The acoustic wave device of claim 2, wherein the edge region extends partially or entirely in the plurality of first electrode fingers and the plurality of second electrode fingers.

4. The acoustic wave device of claim 2, wherein the apodization pattern comprises a first apodization edge and a second apodization edge, and wherein:
the plurality of first electrode fingers extend from a first busbar towards the first apodization edge;
the plurality of second electrode fingers extend from a second busbar towards the second apodization edge; and
the edge region is positioned between the first apodization edge and the first busbar or between the second apodization edge and the second busbar.

5. The acoustic wave device of claim 4, further comprising a plurality of first dummy electrodes extending from the second bus bar and a plurality of second dummy electrodes extending form the first bus bar, the plurality of first dummy electrodes each aligned with a respective first electrode finger in the width direction and separated from the respective first electrode finger by a first gap, the plurality of second dummy electrodes each aligned with a respective second electrode finger in the width direction and separated from the respective second electrode finger by a second gap.

6. The acoustic wave device of claim 5, wherein the edge region is positioned:
between the first apodization edge and the second apodization edge;
between the first busbar and the first gaps or between the second bus bar and the second gaps; or
between a first portion of the first apodization edge and a second portion of the first apodization edge, or between a first portion of the second apodization edge and a second portion of the second apodization edge.

7. The acoustic wave device of claim 6, wherein
the at least one of the plurality of first electrode fingers or the plurality of second electrode fingers includes a second edge portion between the two ends of the same respective electrode finger, the wave velocity of the acoustic wave propagating in the second edge portion along the length direction is different from that outside of the edge portion and the second edge portion; and
the second edge portion is positioned symmetrically or asymmetrically to the edge portion in the width direction about a middle position of the interdigital electrode structure in the width direction.

8. The acoustic wave device of claim 7, wherein a maximum distance between an end of an electrode finger and a closest edge of a respective edge portion is greater than zero.

9. The acoustic wave device of claim 4, wherein the first apodization edge or the second apodization edge comprises a repeated pattern or a non-repeated pattern comprising at least one of a cosine wave pattern, a sine wave pattern, an arccosine pattern, a modified arccosine pattern, a multi-arccosine pattern, a weighted dummy electrode pattern, a slanted apodization pattern, a random apodization, a saw-shape pattern, a triangular-shape pattern, or an intermittent wave pattern.

10. The acoustic wave device of claim 9, wherein the first apodization edge and the second apodization edge have a same shape or are symmetric to each other.

11. The acoustic wave device of claim 1, where a width of the edge portion in the length direction is less than 2λ, λ being a wavelength of the acoustic wave propagating in the interdigital electrode structure.

12. The acoustic wave device of claim 11, wherein, in the length direction, the width of the edge portion is different from a width of the rest of the respective electrode finger.

13. The acoustic wave device of claim 1, wherein:
the edge portion comprises an electrode layer disposed over the piezoelectric layer and a cover layer disposed over the electrode layer; and
the cover layer comprises at least one of silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material, or an insulating material.

14. The acoustic wave device of claim 1, wherein the edge region comprises a first cover layer over the piezoelectric layer between adjacent electrode fingers and the edge portion comprises a second cover layer disposed over an electrode layer, wherein:
the first cover layer is aligned with the second cover layer in the width direction; and
the first and second cover layers comprise at least one of silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material, or an insulating material.

15. The acoustic wave device of claim 1, wherein the edge region comprises a cover layer over the piezoelectric layer between adjacent electrode fingers and the edge portion comprises an electrode layer, wherein:
the cover layer is aligned with the edge portion in the width direction; and
the cover layer comprises at least one of silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material, or an insulating material.

16. The acoustic wave device of claim 15, wherein the edge region further comprises a second cover layer under a respective electrode finger, and wherein the second cover layer comprises at least one of silicon oxide (SiO), silicon nitride (SiN), tantalum oxide (TaₓO_{y}), silicon (Si), aluminum oxide (AlₓO_{y}), aluminum (Al), titanium (Ti), copper (Cu), gold (Au), a metallic material, a semiconductor material, or an insulating material.

17. The acoustic wave device of claim 5, wherein:
a first distance between one of a first electrode finger or a second electrode finger and a respective periodic apodization function is less than a first predetermined percentage of an amplitude of the respective periodic apodization function; and
a second distance between one of a first dummy electrode or a second dummy electrode and a respective periodic apodization function is less than a second predetermined percentage of the amplitude of the respective periodic apodization function.

18. The acoustic wave device of claim 17, wherein the first percentage and the second percentage are each equal to or less than about 30%.

19. The acoustic wave device of claim 17, wherein a minimum overlap between adjacent first electrode finger and second electrode finger is equal to or greater than zero.

20.-32. (canceled)

33. A coupled resonator filter, comprising a plurality of acoustic resonators arranged in a length direction, wherein each of the acoustic resonators comprises:
a piezoelectric layer; and
a plurality of interdigital electrode structures over the piezoelectric layer, the plurality of interdigital electrode structures being insulated from one another, wherein each of the plurality of interdigital electrode structures comprises:
a plurality of first electrode fingers and a plurality of second electrode fingers extending in a width direction, the plurality of first electrode fingers and the plurality of second electrode fingers interleaved with one another along a length direction, the length direction being different from the width direction, wherein:
at least one of the plurality of first electrode fingers or the plurality of second electrode fingers includes an edge portion between two ends of a respective electrode finger, a wave velocity of an acoustic wave propagating in the edge portion along the length direction is different from that outside of the edge portion; and
the at least one of the plurality of first electrode fingers or the plurality of second electrode fingers is apodized with an apodization pattern.

34.-37. (canceled)
